(19) United States
(12) Patent Application Publication
(10) Pub. No.: US 2014/0374715 A1
(43) Pub. Date: Dec. 25, 2014

(54) METHOD FOR FABRICATING ORGANIC ELECTRONIC DEVICE HAVING SEPARATE PATTERNS USING ORGANIC FIBER, AND ORGANIC ELECTRONIC DEVICE HAVING THE ORGANIC FIBER

(71) Applicant: POSTECH ACADEMY – INDUSTRY FOUNDATION, Gyeongsangbuk-do (KR)

(72) Inventors: Tae Woo LEE, Gyeongsangbuk-do (KR); Him Chan CHO, Dalseo-gu (KR)

(21) Appl. No.: 14/307,855

(22) Filed: Jun. 18, 2014

(30) Foreign Application Priority Data
Jun. 21, 2013 (KR) 10-2013-0071963
Jun. 10, 2014 (KR) 10-2014-0069847

(51) Int. Cl. H01L 51/00; H01L 51/50

(52) U.S. Cl. CPC H01L 51/0004; H01L 51/5088; H01L 51/5056; H01L 51/5072; H01L 51/5092; H01L 51/0036; H01L 51/0035
USPC 257/40; 438/46

(57) ABSTRACT

An organic electronic device is provided. The organic electronic device includes a substrate and an organic fiber disposed on the substrate. Material patterns are disposed on exposed surfaces of the substrate at both sides of the organic fiber and separated by the organic fiber. By arranging the organic fiber and then coating the organic fiber with a material layer to form material patterns separated by the organic fiber, very simple, fast, and sufficient separation of patterns may be implemented with no complicated process such as a lithography process, used in the art.

### CROSS-REFERENCE TO RELATED APPLICATION

This application claims priority to and the benefit of Korean Patent Applications No. 2013-0071963, filed on Jun. 21, 2013 and No. 2014-0069847, filed on Jun. 10, 2014, the disclosure of which is incorporated herein by reference in its entirety.

### BACKGROUND

1. Field of the Invention

The present invention relates to a method of forming a pattern using an aligned organic fiber, and more specifically, to a method of separating a unit cell of an organic electronic device.

2. Discussion of Related Art

Recently, organic light-emitting diodes (OLEDs) have been succeeded in commercialization for their advantages, such as a simple fabrication process, a light weight, a thin panel, a wide viewing angle, a fast response, and flexibility. In order to implement a display based on an OLED, an anode and a cathode need to form patterns crossing each other and form a pixel array of the OLED.

As the anode, indium tin oxide (ITO) is widely used. ITO may be easily patterned on a stable substrate and there are various methods to pattern the ITO. However, patterning of the cathode has a limitation since an organic layer disposed under the cathode should not be affected.

The patterning of the cathode may be roughly classified into three methods. A first method is forming a pattern by attaching a shadow mask to an OLED before depositing the cathode. The method is commonly used since a process thereof is simple. However, the method has some problems, such as difficulties in fabrication of large area devices, low resolution, and low throughput, to be industrially applied.

A second method is forming a cathode-separating layer on an OLED to separate the cathode. However, since the method includes, in many cases, a lithography process using a photoresist, processes are very complicated and performance of the OLED may be degraded during the processes (refer to K. Nagayama, T. Yahagi, H. Nakada, T. Tohma, T. Watanabe, K. Yoshida, & S. Miyaguchi, Jpn. J. Appl. Phys. 36, L1555 (1997) and J. Rhee, J. Park, S. Kwon, H. Yoon, & H. H. Lee, Adv. Mater. 15, 1075 (2003)).

A third method is ablating a fabricated OLED using high power laser. However, the method has a problem in which patterns are not clear (refer to C. Liu, G Zhu, & D. Liu, Displays, 29, 536 (2008)).

### SUMMARY OF THE INVENTION

In an organic electronic device including a vulnerable organic layer, since separation of pixels includes a lithography process, the process is very complicated and time-consuming. The present invention is directed to a method of effectively separating an organic layer by replacing the complicated process with an organic fiber patterning process, which is very simple, fast, and easy to fabricate a large area device.

According to an aspect of the present invention, there is provided an organic electronic device. The organic electronic device includes a substrate and an organic fiber disposed on the substrate. Material patterns separated by the organic fiber are disposed on exposed surfaces of the substrate at both sides of the organic fiber.

In some embodiments, the material patterns may include at least one of an organic semiconductor layer, an organic conductive layer, an inorganic semiconductor layer, and an inorganic metal electrode.

In other embodiments, a first electrode may be disposed between the organic fiber and the substrate. The material patterns may include a second electrode. Further, the material patterns may include a sequentially stacked organic active layer and second electrode, and the organic active layer may be an organic light emitting layer or an organic photoelectric conversion layer. At least one of a hole injection layer and a hole transport layer may be disposed between the first electrode and a bottom of the organic fiber. At least one of the hole injection layer and the hole transport layer may be a hole conducting polymer layer. The hole-conducting polymer layer may include polythiophene, polyaniline, polypyrrole, polystyrene, sulfonated polystyrene, poly (3,4-ethylenedioxythiophene), a self-doped conductive polymer, a derivative thereof, or a blend of two or more thereof. At least one of an electron transport layer and an electron injection layer may be disposed between the organic active layer and the second electrode.

In still other embodiments, the organic fiber may be an insulating polymer fiber. A cross-section of the organic fiber may have a circular or oval shape. The organic fiber may have a diameter of 10 nm to 100 p.m. The organic fiber may be a plurality of organic fibers spaced apart from each other, and an angle formed by the organic fibers may be in the range of 0° to 10°. In addition, each of the plurality of organic fibers may have straightness with respect to a diameter thereof within the range of 0% to 10%.

According to another aspect of the present invention, there is provided a method of forming an organic electronic device. First, organic fibers are arranged on a substrate. A material layer is deposited on the substrate, on which the organic fibers are formed, to form material patterns separated by the organic fibers on the substrate.

In some embodiments, the organic fibers may be formed by printing an organic solution obtained by mixing an organic material in distilled water or an organic solvent on the substrate. The organic material may be an organic insulating polymer selected from a group consisting of PEO(Polyethylene oxide), PS(Polystyrene), PCL(Polycaprolactone), PAN(Polyacrylonitrile), PMMA(Poly(methyl methacrylate)), Polyimide, PVDF(Poly(vinylidene fluoride)), PVK(Poly(n-vinylcarbazole)), PVC(Polyvinylchloride), and photoresist. The organic solvent may be a solvent selected from a group consisting of dichloroethylene, trichloroethylene, chloroform, chlorobenzene, dichlorobenzene, styrene, dimethylformamide, dimethylsulfoxide, xylene, toluene, cyclohexene, isopropyl alcohol, ethanol, acetone and mixtures thereof.

The printing may be performed using electric field aided robotic nozzle printing, direct tip drawing, meniscus-guided direct writing, melt spinning, wet spinning, dry spinning, gel spinning, or electrospinning.

The electric field aided robotic nozzle printing may be performed using a printer including a solution storage apparatus supplying the organic solution, a nozzle discharging the organic solution received from the solution storage apparatus, a voltage applying apparatus applying high voltage to the nozzle, a collector having a flat shape and being movable, a robot stage moving the collector along x and/or y directions, a micro distance controller controlling the distance between the nozzle and the collector along z direction, and a base plate maintaining flatness of the collector and preventing vibrations generated by an operation of the robot stage. A distance between the nozzle and the collector may be in the range of about 10 μm to about 20 mm.

The printing of the organic fibers may include adding the organic solution into the solution storage apparatus, discharging the organic solution from the nozzle while applying high voltage on the nozzle by using the voltage applying apparatus, and aligning, on a substrate placed on the collector while moving the collector, the organic fibers formed from the organic solution being discharged from the nozzle.

In other embodiments, the material layer may include at least one of an organic semiconductor layer, an organic conductive layer, an inorganic semiconductor layer, and an inorganic metal electrode.

In still other embodiments, a first electrode may be formed on the substrate before the organic fibers are arranged, and the depositing the material layer may include depositing a second electrode. The depositing the material layer may further include depositing an organic active layer before depositing the second electrode. The organic active layer may be an organic light emitting layer or an organic photoelectric conversion layer. At least one of a hole injection layer and a hole transport layer may be formed on the first electrode before arranging the organic fibers. At least one of the hole injection layer and the hole transport layer may be a hole conducting polymer layer formed by a liquid-phase process. The hole-conducting polymer layer may include polythiophene, polyaniline, polypyrrole, polystyrene, sulfonated polystyrene, poly (3,4-ethylenedioxythiophene), a self-doped conductive polymer, a derivative thereof, or a blend of two or more thereof.

In still other embodiments, a first organic layer may be formed on the first electrode before arranging the organic fibers. The depositing the material layer may further include depositing a second organic layer including an organic active layer before depositing the second electrode. The organic active layer may be an organic light emitting layer or an organic photoelectric conversion layer. The first organic layer may be formed by a liquid-phase process.

### BRIEF DESCRIPTION OF THE DRAWINGS

The above and other objects, features, and advantages of the present invention will become more apparent to those of ordinary skill in the art by describing in detail exemplary embodiments thereof with reference to the accompanying drawings, in which:

FIG. 1 is a cross-sectional view schematically showing a method of forming a pattern using an organic fiber according to an embodiment of the inventive concept;

FIGS. 2A and 2B are respectively a perspective view and a side view schematically showing a field-aided robotic nozzle printer according to an embodiment of the present invention;

FIGS. 3A to 3B are plan views showing a method of forming a pattern of an organic electronic device according to an embodiment of the inventive concept;

FIGS. 4A and 4B are cross-sectional views respectively taken along lines I-I′ of FIGS. 3A and 3B;

FIG. 5 is an enlarged cross-sectional view of a V portion in FIG. 4B;

FIG. 6 is a cross-sectional view showing an organic electronic device according to an embodiment of the inventive concept;

FIG. 7A shows an optical microscope (OM) photograph of a PVK fiber pattern formed by Preparative Example of a fiber pattern;

FIG. 7B shows an SEM photograph and a diameter distribution chart of a PVK fiber pattern formed by Preparative Example of a fiber pattern;

FIG. 8 is a schematic diagram showing a process of forming an organic light emitting diode according to Preparative Example 1 of an organic light emitting diode;

FIG. 9 is a stereoscopic micrograph taken while driving an organic light emitting diode according to Preparative Example 1 of an organic light emitting diode;

FIGS. 10A and 10B are SEM photographs respectively showing a cross-section and a side surface of a result according to a cathode separation example;

FIGS. 11A, 11B, 11C, and 11D are a graph showing current density vs. voltage characteristics (11A), a graph showing brightness vs. voltage characteristics (11B), a graph showing current efficiency vs. current density characteristics (11C), and a graph showing power efficiency vs. voltage characteristics (11D), of organic light emitting diodes according to Preparative Examples 1 to 4, and Comparative Example;

FIG. 12A is a plan view showing an organic light emitting diode according to Preparative Example 5 of an organic light emitting diode, and FIG. 12B is a photograph taken while driving an organic light emitting diode according to Preparative Example 5 of an organic light emitting diode; and

FIG. 13 is a photograph taken while driving an organic light emitting diode according to Preparative Example 6 of an organic light emitting diode.

### DETAILED DESCRIPTION OF EXEMPLARY EMBODIMENTS

Example embodiments of the present invention are disclosed herein. However, specific structural and functional details disclosed herein are merely representative for purposes of describing example embodiments of the present invention, and thus example embodiments of the present invention may be embodied in many alternate forms and should not be construed as limited to example embodiments of the present invention set forth herein.

It will be understood that when a layer is referred to as being “on” another layer or a substrate, the layer may be formed directly on the other layer or the substrate, or an intervening layer may exist between the layer and the other layer or the substrate. Furthermore, throughout this disclosure, directional terms such as “upper,” “upper (portion),” and “upper surface” may also encompass meanings of “lower,” “lower (portion),” and “lower surface.” That is, a spatial direction is construed as a relative direction, instead of an absolute direction.

In the drawings, the thicknesses of layers and regions may be exaggerated or omitted for clarity. Like numerals refer to like elements throughout the description of the figures.

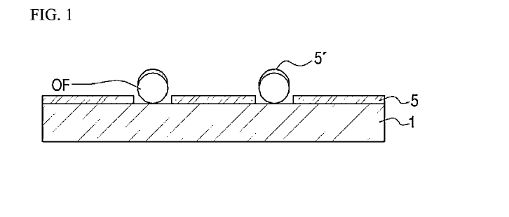

FIG. 1 is a cross-sectional view schematically showing a method of forming a pattern using an organic fiber according to an embodiment of the inventive concept.

Referring to FIG. 1, organic fibers OF are disposed on a substrate 1. The organic fibers OF may be arranged on the substrate 1, and may have a uniform diameter. For example, the organic fibers OF may have a diameter of about 10 nm to about 100 μm, and preferably about 100 nm to about 100 μm.

The organic fibers OF may be selected from a random orientated pattern and aligned patterns. The organic fibers OF may have an angular error range of 0° to 10° in an angle formed by two or more fibers spaced apart from each other. In addition, the fibers may be in parallel. Further, the fibers may have straightness within a range of 0% to 10% in a printing direction of each fiber. Further, the organic fibers OF may be uniformly spaced apart from each other. For example, aligned patterns of the organic fibers OF may be spaced about 10 nm to about 100 cm apart from each other. Meanwhile, patterns which do not satisfy the above-described conditions are referred to as random patterns. Random patterns may be a combination of various shapes, such as a circle, an oval, a curve, a straight line, and a roll line.

The organic fibers OF may be formed to have a circular or oval cross-section. The organic fibers OF having the circular or oval cross-section may be formed using a printer. The printer may arrange the organic fibers OF by discharging an organic solution from an organic solution storage to the substrate 1. The organic solution may be formed by mixing an organic material in distilled water or an organic solvent. The organic solvent may include, for example, dichloroethylene, trichloroethylene, chloroform, chlorobenzene, dichlorobenzene, styrene, dimethylformamide, dimethylsulfoxide, xylene, toluene, cyclohexene, isopropyl alcohol, ethanol, acetone or mixtures thereof, but is not limited thereto. The organic solvent may include co-solvent. For example, the organic solvent may be a mixture of dichloroethylene and chlorobenzene.

The organic fibers OF may be insulating polymer fibers. More specifically, the organic material may be an insulating polymer. The insulating polymer includes a polymer having a significantly low charge transporting ability of 10⁻⁶ cm²V⁻¹ s⁻¹ or less. The insulating polymer may be selected from a group consisting of PEO(Polyethylene oxide), PS(Polystyrene), PCL(Polycaprolactone), PAN(Polyacrylonitrile), PMMA(Poly(methyl methacrylate)), Polyimide, PVDF(Poly(vinylidene fluoride)), PVK(Poly(n-vinylcarbazole)), PVC(Polyvinylchloride), and photoresist.

The printer may be an apparatus performing electric field aided robotic nozzle printing, direct tip drawing (J. Shi, M. Guo, B. Li, Appl. Phys. Lett, 93, 121101 (2008)), meniscus-guided direct writing (J. T. Kim, S. K. Seol, J. Pyo, J. S. Lee, J. H. Je, G. Margaritondo, Adv. Mater. 23, 1968-1970 (2011)), melt spinning (S. Kase, T. Matsuo, J. Polymer Sci. Part A, 3, 2541-2554 (1965)), wet spinning (G. C. East, Y. Qin, J. Appl. Polymer Sci. 50, 1773-1779 (1993)), dry spinning (S. Gogolewski, A. J. Pennings, Polymer, 26, 1394-1400 (1985)), gel spinning (R. Fukae a, A. Maekawa, O. Sangen, Polymer, 46, 11193-11194 (2005)) or electrospinning (V. Thavasi, G. Singh, S. Ramakrishna, Energy Environ. Sci., 1, 205-221 (2008)), but is not limited thereto.

Next, material layers 5 and 5′ may be applied on the substrate 1 on which the organic fibers OF are arranged. The material layers 5 and 5′ may be formed on a surface of the substrate 1 which is not covered by the organic fibers OF, and on the organic fibers OF. Here, the material layer or material pattern 5 formed on the surface of the substrate 1 may not be connected to the material layer or material pattern 5′ formed on the organic fibers OF due to the organic fibers OF. In addition, the cross-sectional shape of the organic fibers OF, that is, a circular or oval cross-sectional shape may make such separation of the material layers 5 and 5′ easier. The material layer 5 formed on the surface of the substrate 1 may be at least one of an organic semiconductor pattern, an organic conductor pattern, an inorganic semiconductor pattern, and an inorganic metal electrode pattern in an organic electronic device. The inorganic semiconductor layer may include at least one selected from the group consisting of indium tin oxide, indium zinc oxide, indium gallium zinc oxide, tin oxide, zinc oxide, gallium zinc oxide, nickel oxide, copper oxide, and aluminum oxide. In this way, when using the organic fibers OF, very simple, fast, and sufficient separation of patterns may be implemented with no complicated process such as a lithography process, used in the art. In addition, a variety of organic electronic devices, such as organic thin film transistors, organic light emitting diodes, organic solar cells, or organic photodetectors, may be fabricated using the method of forming a pattern according to the embodiment of the inventive concept.

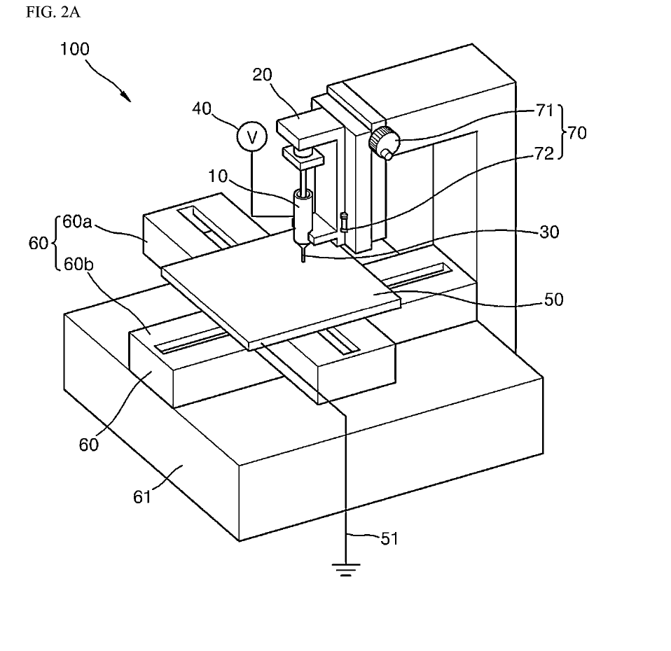

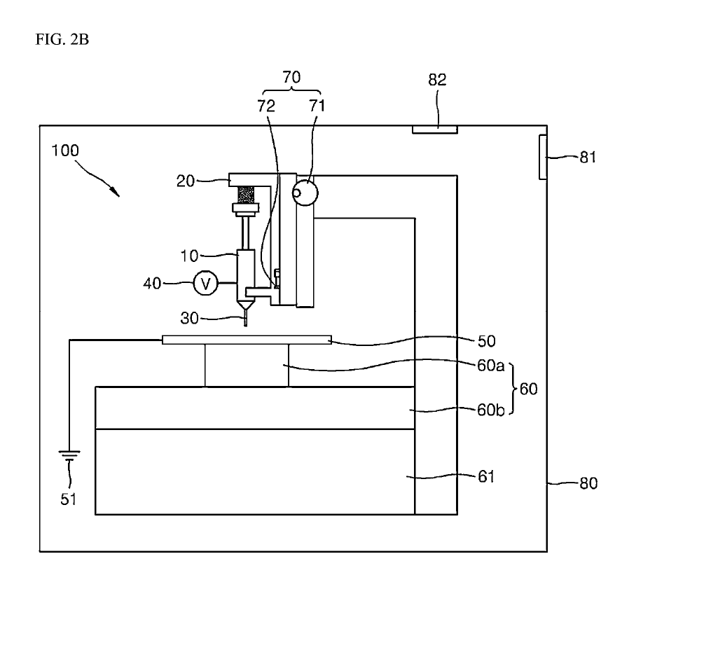

FIGS. 2a and 2b respectively show a schematically illustrated perspective view and a side view of an electric field aided robotic nozzle printer according to an embodiment of the present disclosure. This electric field aided robotic nozzle printer can be used to dispose the organic fiber described referring to the FIG. 1 on a substrate.

Referring to FIGS. 2a and 2b, the electric field aided robotic nozzle printer 100 according to the present disclosure includes a solution storage apparatus 10, a discharge controller 20, a nozzle 30, a voltage applying apparatus 40, a collector 50, a robot stage 60, a base plate (precision stone surface) 61, and a micro distance controller 70.

The solution storage apparatus 10 stores an organic solution and supplies it to a nozzle 30 so that the organic solution can be discharged through the nozzle 30. The solution storage apparatus 10 may be in the form of a syringe. The solution storage apparatus 10 may be made by using plastic, glass or stainless steel, but is not limited thereto. The solution storage apparatus has a capacity volume in the range of about 1 μl to about 5,000 ml, but is not limited thereto. The capacity of the solution storage apparatus may be in the range of about 10 μl to about 50 ml. When the solution storage apparatus is made of stainless steel there is provided a gas injector (not shown) for injecting gas into the solution storage apparatus 10, thus enabling the discharge of the organic solution into the outside of the solution storage apparatus by using gas pressure. Meanwhile, the solution storage apparatus 10 may be formed in plurality in order to form organic fibers or wirers having a core shell structure.

The discharge controller 20 serves to apply a pressure on an organic solution in the solution storage apparatus 10 to discharge the organic solution at a predetermined rate through the nozzle 30. The discharge controller 20 may be a pump or a gas pressure controller. The discharge controller 20 can control the rate of discharging the organic solution in the range of about 1 nl/min to about 50 ml/min. When more than one solution storage apparatus 10 is used, there may be provided a separate discharge controller 20 in each solution storage apparatus 10 so that each solution storage apparatus 10 can operate independently. When solution storage apparatus 10 is made of stainless steel, a gas pressure controller (not shown) may be used as a discharge controller 20.

The nozzle 30 are configured to discharge an organic solution received from the solution storage apparatus 10. The organic solution being discharged can form droplets at the terminal end of the nozzle 30. The nozzle 30 may have a diameter in the range of about 100 nm to about 1.5 mm, but are not limited thereto.

The nozzle 30 may be a single nozzle, a dual-concentric nozzle, a triple-concentric nozzle, a split nozzle or a multi nozzle. When organic fibers with a core shell structure are formed, more than two different kinds of organic solutions can be discharged by using a dual-concentric nozzle or a triple-concentric nozzle. In this case, two or three solution storage apparatuses 10 may be connected to the dual-concentric nozzle or the triple-concentric nozzle.

A voltage applying apparatus 40 is configured to apply high voltage to the nozzles 30, and it can include a high voltage generating apparatus. The voltage applying apparatus 40 may be electrically connected to the nozzles 30, for example, through the solution storage apparatus 10. The voltage applying apparatus 40 can apply voltage in the range of about 0.1 kV to about 50 kV, but is not limited thereto. An electric field is present between the nozzles 30 that high voltage is applied to by the voltage applying apparatus 40, and the grounded collector 50. And by the electric field, droplets formed at the terminal ends of the nozzle 30 form Taylor cones, and organic fibers are continuously formed from the terminal ends.

The collector 50 is a part to which organic fibers formed from the organic solution discharged from the nozzle 30 are attached. The collector 50 has a flat shape, and is movable on a horizontal plane by a robot stage 60. The collector 50 is configured to be grounded so that it can have a grounding property relative to the high voltage applied to the nozzle 30. Reference numeral 51 indicates that the collector 50 is grounded. The collector 50 can be made of a conductive material, for example, a metal, and have a flatness in the range of about 0.5 μm to about 10 μm (flatness refers to the maximum error value of a real surface from a perfect horizontal surface when the flatness of the perfect horizontal surface is ‘0’, for example, the flatness of a single surface is the distance between the lowest point and the highest point of the surface).

The robot stage 60 is configured to transport the collector 50. The robot stage 60, configured to be driven by a servo motor, can move at a precise velocity. The robot stage 60 can be controlled, for example, to move in two different directions of x axis and y axis on a horizontal plane. The robot stage 60 may, for example, consist of x axis robot stage 60a, which moves along the x axis, and y axis robot stage 60b, which moves along the y axis. The robot stage 60 may move at intervals in the range of about 10 nm or greater and about 100 cm or less, and preferably, in the range of about 10 μm or greater and about 20 cm or less, but is not limited thereto. The moving speed of the robot stage 60 can be controlled in the range of about 1 mm/min to about 60,000 mm/min, but is not limited thereto. The robot stage 60 is installed on the base plate 61, and the base plate 61 can have a flatness in the range of about 0.1 μm to about 5 μm. The constant distance between the nozzle 30 and the collector 50 can be controlled by the flatness of the base plate 61. In other words, because the base plate 61 has high flatness, the distance between the nozzle 30 and the collector 50, which is positioned on the robot stage 60 moving on the base plate 61, can be maintained. The base plate 61 can provide a precise control over the organic fiber patterns by preventing vibrations generated by the operation of the robot stage 60.

The micro distance controller 70 controls the distance between the nozzle 30 and the collector 50. The distance between the nozzle 30 and the collector 50 can be controlled by vertically transporting the solution storage apparatus 10 and the nozzle 30 via the micro distance controller 70.

The micro distance controller 70 may consist of a jog 71 and a micrometer 72. The jog 71 is used for coarse adjustment of a distance in the range of from a few mm to a few cm, whereas the micrometer 72 is used for fine adjustment of a distance in the range of about 10 μm or longer. First, nozzle 30 is neared to the collector 50 by using the jog 71, and then the distance between the nozzles 30 and the collector 50 are precisely adjusted by the micrometer 72. The distance between the nozzle 30 and the collector 50 can be controlled in the range of about 10 μm to about 20 mm. For example, the collector 50, which is parallel to the horizontal X-Y plane, can move in the X-Y plane by the robot stage 60, and the distance between the nozzle 30 and the collector 50 can be adjusted along the direction of Z axis by the micro distance controller 70.

The three dimensional path of nanofibers being spun out of the nozzles in electrospinning was calculated by D. H. Reneker, A. L. Yarin, H. Fong, S. Koombhongse, ‘Bending instability of electrically charged liquid jets of polymer solutions in electrospinning’ J. Appl. Phys., 87, 9, 4531-4546 (2000). According to the above journal article, the greater the distance between the nozzles and the collector, the greater the perturbation of the nanofibers, as shown in the below Equations:

$$\begin{matrix}x = {10}^{- 3} L cos ( \frac{2 π}{λ} z ) \frac{h - z}{h} & Equation ( 1 a ) \\ y = {10}^{- 3} L sin ( \frac{2 π}{λ} z ) \frac{h - z}{h} & Equation ( 2 a )\end{matrix}$$

In the above Equations, x and y respectively represent the positions in the x axis and y axis directions on a flat plane, L is a constant for a length scale, λ, is a perturbation wavelength, z is a vertical position of organic fibers relative to collector (z=0), and h is the distance between the nozzles and the collector. From the Equations (1a) and (1b), it is noted that, for the same z value, the greater the distance h between the nozzles and the collector, the greater the values of x and y, which represent the perturbation of the organic fibers.

In fact, the organic fibers, which are generated from the droplets in the terminal ends of the nozzles and extended therefrom, are almost in the form of a straight line along the direction of z axis, which is perpendicular to the collector, near the nozzles where the organic fibers are generated. However, as the organic fibers extend farther away from the nozzles, the lateral velocity of the organic fibers increases, thereby causing the organic fibers to bend.

In an embodiment of the present disclosure, there is provided an electric field aided robotic nozzle printer 100, which can sufficiently reduce the distance between the nozzle 30 and the collector 50 within a range of ten to a few tens of micrometers, thereby causing the organic fibers to fall onto the collector 50 before they are perturbed. Accordingly, the organic fiber patterns can be formed by the movement of the collector 50.

The formation of the organic fiber patterns by the movement of the collector 50 rather than by the movement of the nozzles can reduce perturbation of the organic fiber patterns, thereby enabling the formation of more precise organic fiber patterns.

Meanwhile, the electric field aided robotic nozzle printer 100 can be installed within a housing 80. The housing 80 can be made of a transparent material. The housing 80 is sealable, and can inject a gas into the housing 80 through a gas injection inlet (not shown). The gas to be injected into the housing 80 includes nitrogen, dry air, and the like, and the injected gas helps to maintain an organic solvent which is readily oxidized in the presence of moisture to be stable. Furthermore, the housing 80 may be provided with a ventilator 81 and a lamp 82. The ventilator 81 and the lamp 82 can be installed in suitable locations. The ventilator 81 is configured to control the steam pressure (generated from a solvent) in the housing 80, thereby controlling the evaporation rate of the solvent at the time of forming organic fibers. In a robotic nozzle printing requiring a fast evaporation of a solvent, the evaporation of the solvent can be aided by adjusting the speed of the ventilator 81. The evaporation rate of the solvent may influence the shape and electric properties of the organic fibers. When the evaporation rate of the solvent is too fast, it may cause the solution to dry at the nozzle ends before the organic fibers are formed, thus clogging the nozzles. In contrast, when the evaporation rate of the solvent is too slow, it prevents formation of solid organic fibers, and they may be placed in the collector in a liquid state. The organic solution line in liquid state cannot be used in the manufacture of devices because its electric properties are poor. As such, the evaporation rate of the solvent has an impact on the formation of organic fibers and their properties, and thus the ventilator (81) can play an important role in the formation of organic fibers.

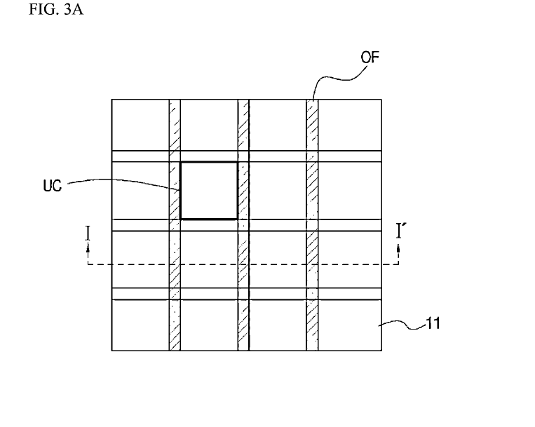

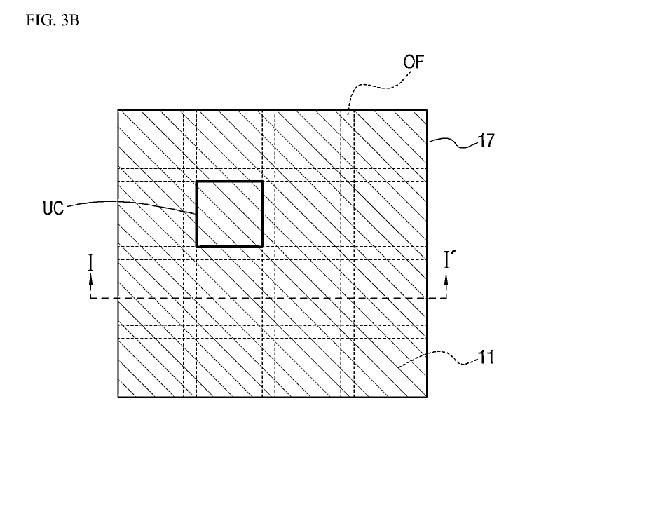

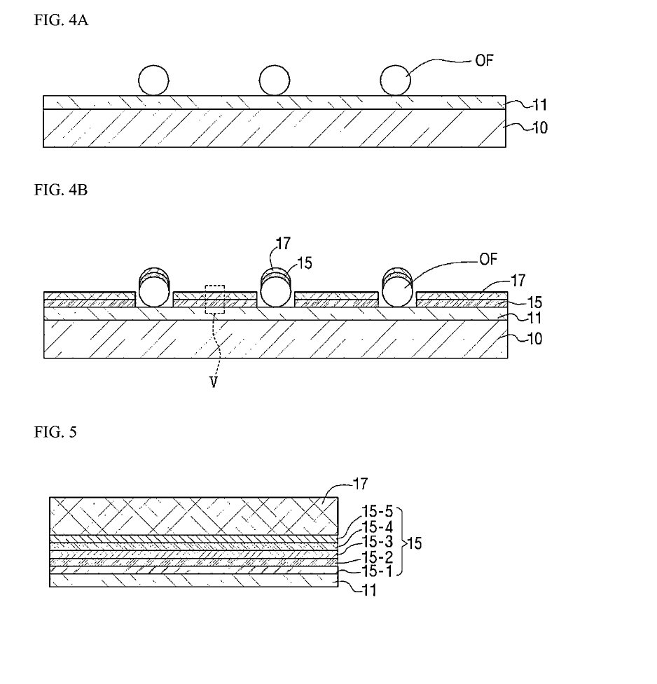

FIGS. 3A to 3B are plan views showing a method of forming a pattern of an organic electronic device according to an embodiment of the inventive concept. FIGS. 4A and 4B are cross-sectional views respectively taken along lines I-I′ of FIGS. 3A and 3B. FIG. 5 is an enlarged cross-sectional view of a V portion in FIG. 4B. The organic electronic device may be an organic light emitting diode, an organic solar cell, or an organic photodetector.

Referring to FIGS. 3A and 4A, a first electrode 11 is formed on a substrate 10. The substrate 10 may include silicon, silicon oxide, a metal foil, a metal oxide, a polymer substrate, or a combination of two or more thereof. The metal foil may be a copper foil, an aluminum foil, or a stainless steel foil. The metal oxide may be aluminum oxide, molybdenum oxide, indium oxide, tin oxide, indium tin oxide, or vanadium oxide. The polymer substrate may be a kapton foil, polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), or cellulose acetate propionate (CAP), but the present invention is not limited thereto.

The first electrode 11 may be a plurality of patterns arranged in parallel in one direction. The first electrode 11 may be an anode. The first electrode 11 may be a reflective electrode or a transmissive electrode. The reflective electrode may include or may be magnesium (Mg), aluminum (Al), silver (Ag), Ag/ITO, Ag/IZO, aluminum-lithium (Al—Li), calcium (Ca), magnesium-indium (Mg—In), or magnesium-silver (Mg—Ag). The transmissive electrode may include or may be indium tin oxide (ITO), indium zinc oxide (IZO), tin oxide (SnO2), zincoxide(ZnO), a metal oxide/metal/metal oxide multilayer, metal grid, graphene, reduced graphene oxide, or carbon nanotube. The first electrode 11 may be formed using a sputtering method, an evaporation method, an ion beam evaporation method, or an coating method.

Organic fibers OF are disposed on the first electrode 11. The first electrode 11 may be formed by patterning using a photolithography process, but is not limited thereto. In another embodiment, the first electrode 11 may be formed by disposing the organic fibers OF, then depositing or coating with a material for forming the first electrode 11 on the substrate 10 on which the organic fibers OF are disposed, and then patterning the first electrode 11. Detailed descriptions of the organic fibers OF refer to the above descriptions with reference to FIG. 1.

The organic fibers OF may be arranged to cross the first electrode 11, and may have a plurality of patterns in parallel. An exposed portion of the first electrode 11 adjacent to the organic fibers OF may be defined as a unit cell UP of the organic electronic device.

Referring to FIGS. 3B, 4B, and 5, an organic layer 15 and a second electrode 17 may be sequentially deposited on the substrate 10 on which the organic fibers OF are arranged. The organic layer 15 and the second electrode 17 may be formed on an overall portion which is not covered by the organic fibers OF, in particular, a surface of the first electrode 11, and on the organic fibers OF. Here, a cross-sectional shape, that is, a circular or oval cross-sectional shape, of the organic fibers OF may function to prevent the organic layer 15 and the second electrode 17 formed on the first electrode 11 from being connected to the organic layer 15 and the second electrode 17 formed on the organic fibers OF. In this way, when using the organic fibers OF, very simple, fast, and sufficient separation of patterns may be implemented with no complicated process such as a lithography process, used in the art. However, the embodiment of the present invention is not limited thereto. The organic layer 15 may be formed on the first electrode 11 before the organic fibers OF are formed, then the second electrode 17 may be deposited on the substrate 10 on which the organic fibers OF are arranged, and then only the second electrode 17 may be patterned using the organic fibers OF.

The organic layer 15 may include a hole injection layer 15-1, a hole transport layer 15-2, an organic active layer 15-3, an electron transport layer 15-4, and an electron injection layer 15-5. The organic active layer 15-3 can be formed using different materials according to the kind of the organic device as described later. Meanwhile, at least one of the hole injection layer 15-1, the hole transport layer 15-2, the electron transport layer 15-4, and the electron injection layer 15-5 can be omitted.

The hole injection layer 15-1 or the hole transport layer 15-2 may include a material used as a hole conducting material. One of these layers may include different hole conducting materials. The hole conducting material may be, for example, mCP (N,N-dicarbazolyl-3,5-benzene); PEDOT:PSS (poly(3,4-ethylenedioxythiophene):polystyrenesulfonate); NPD (N,N′-di(1-naphthyl)-N,N′-diphenylbenzidine); N,N′-diphenyl-N,N′-di(3-methylphenyl)-4,4′-diaminobiphenyl(TPD); N,N′-diphenyl-N,N′-dinaphthyl-4,4′-diaminobiphenyl; N,N,N′N′-tetra-p-tolyl-4,4′-diaminobiphenyl; N,N,N′N′-tetraphenyl-4,4′-diaminobiphenyl; porphyrin compound derivatives such as cupper(II)1,10,15,20-tetraphenyl-21H,23H-porphyrin, etc.; TAPC(1,1-Bis[4-[N,N′-Di(p-tolyl)Amino]Phenyl]Cyclohexane); triarylamine derivatives such as N,N,N-tri(p-tolyl)amine, 4,4′,4′-tris[N-(3-methylphenyl)-N-phenylamino]triphenylamine; carbazole derivatives such as N-phenyl carbazole and polyvinyl carbazole; phthalocyanine derivatives such as metal free-phthalocyanine and cupper phthalocyanine; starburst amine derivatives; enamine stilbene derivatives; aromatic tertiary amine and styryl amine derivatives; or polysilane. The hole conducting material may play a role as an electron blocking layer.

The electron transport layer 15-4 may be TSPO1(diphenylphosphine oxide-4-(triphenylsilyl)phenyl), tris(8-hydroxyquinoline) aluminum (Alq3), 2,5-diarylsilole derivatives (PyPySPyPy), perfluorinated compound (PF-6P), COTs (Octasubstituted cyclooctatetraene), TAZ, 4,7-diphenyl-1,10-phenanthroline (Bphen), BCP, or BAlq.

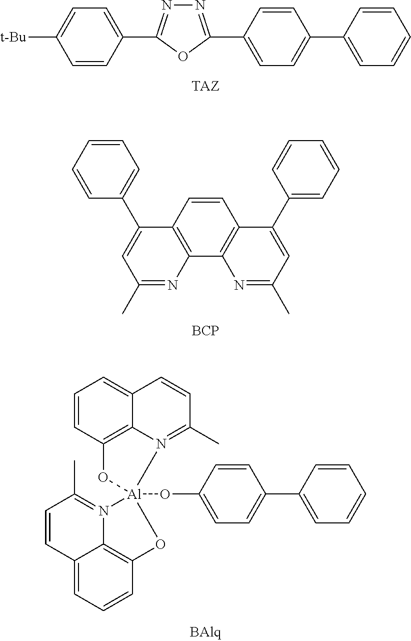

The electron injection layer 15-5 may be LiF, NaCl, CsF, Li₂O, BaO, BaF₂, or Liq (lithiumquinolate).

The hole injection layer 15-1, the hole transport layer 15-2, the organic active layer 15-3, the electron transport layer 15-4, and the electron injection layer 15-5 can, irrespectively, be formed using vacuum deposition or coating, for example, spray coating, spin-coating, dipping, printing, doctor blade coating or electrophoresis.

The second electrode 17 may be a cathode. The cathode is a conducting layer having lower working function than the anode. The cathode may be, for example, a metal such as aluminum (Al), magnesium (Mg), calcium (Ca), sodium (Na), potassium (K), indium (In), yttrium (Y), lithium (Li), silver (Ag), lead (Pb), cesium (Cs) or the combination thereof. The second electrode 17 may be formed using sputtering method, vapor deposition, or ion beam deposition. When the organic electronic device is an organic light emitting device, the organic active layer 15-3 may be an organic light emitting layer. The organic light emitting layer may consists of singular light emitting material, or may have host and dopant.

Examples of the host include Alq₃, 4,4′-N,N′-dicarbazole-biphenyl (CBP), 9,10-di(naphthalene-2-yl)anthracene (ADN), TCTA, 1,3,5-tris(N-phenylbenzimidazole-2-yl)benzene (TPBI), 3-tert-butyl-9,10-di(naphtha-2-yl)anthracene (TBADN), E3, BeBq₂, or a composition thereof, but are not limited thereto.

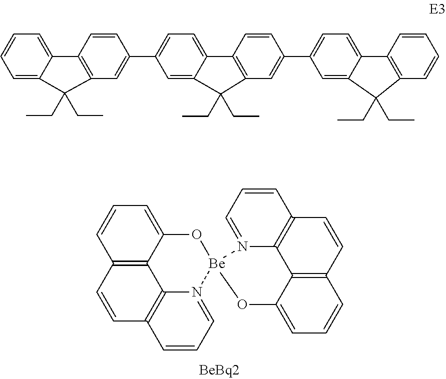

Meanwhile, the host may include ambipolar transport material, hole transport material, or electron transport material.

The ambipolar transport material may be selected from a well-known material having a hole transport ability and an electron transport ability at the same time. For example, the ambipolar transport material may be a tert(9,9-diarylfluorene) derivative (e.g. 2,7-bis[9,9-di(4-methylphenyl)-fluoren-2-yl]-9,9-di(4-methylphenyl)fluorine) (TDAF), 2,7-bis(9,9-spirobifluoren-2-yl)-9,9-spirobifluorene (BDAF), 9,10-di(naphth-2-yl)anthracene (ADN), 2-tert-butyl-9,10-bis-(β-naphthyl)-anthracene (TBADN), 2,6-di(t-butyl)-9,10-di(2-naphthyl)anthracene (2TBADN), 2,6-di(t-butyl)-9,10-di-[6-(t-butyl)(2-naphthyl)]anthracene (3 TBADN), 2-methyl-9,10-bis(naphthalen-2-yl)anthracene (MADN), terfluorene (E3), etc., but is not limited thereto.

The electron transport material may be a material having a greater electron mobility than hole mobility under the same electric field. For example, the electron transport material may be selected from a material for an electron transport layer and/or an electron injection layer of an organic light emitting device. The electron transport material may be tris(8-hydroxyquinoline) aluminum (Alq₃), 2,2′,2″-(benzene-1,3,5-triyl)-tris(1-phenyl-1H-benzimidazole (TPBI), 2,9-dimethyl-4,7-diphenyl-1,10-phenanthroline (BCP), 4,7-diphenyl-1,10-phenanthroline (Bphen), bis(2-methyl-8-quinolinolate)-4-(phenylphenolato)aluminum (Balq), 1,3-bis[2-(2,2′-bipyridine-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), bis(10-hydroxybenzo[h]quinolinato)beryllium (Bepq₂), bis(10-hydroxybenzo[h]quinolinato)-beryllium (Bebq₂), diphenylbis(4-(pyridin-3-yl)phenyl)silane (DPPS), or (1,3,5-tri(p-pyrid-3-yl-phenyl)benzene (TpPyPB), but is not limited thereto.

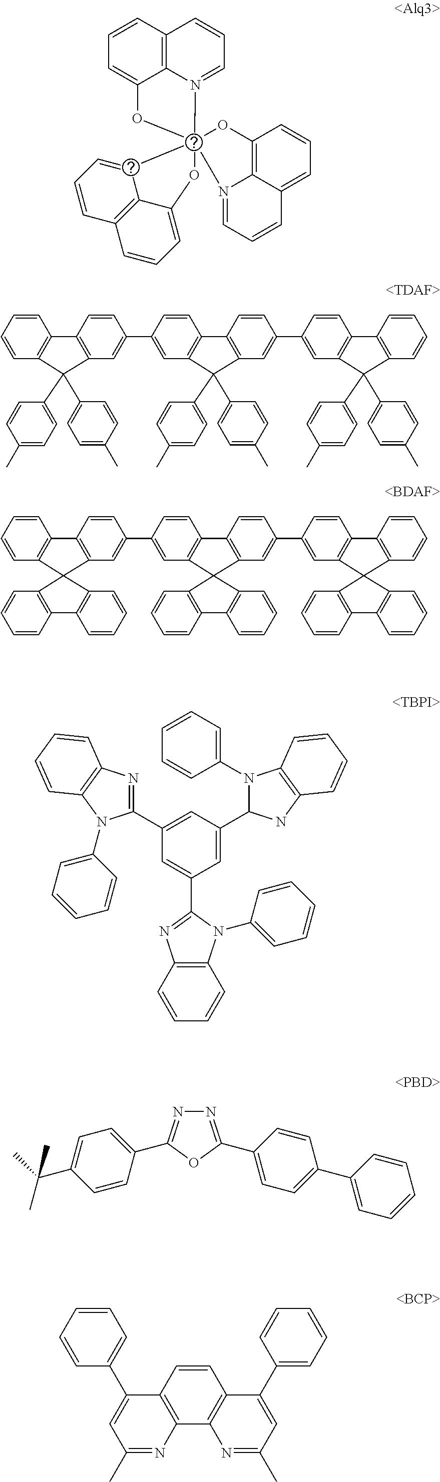

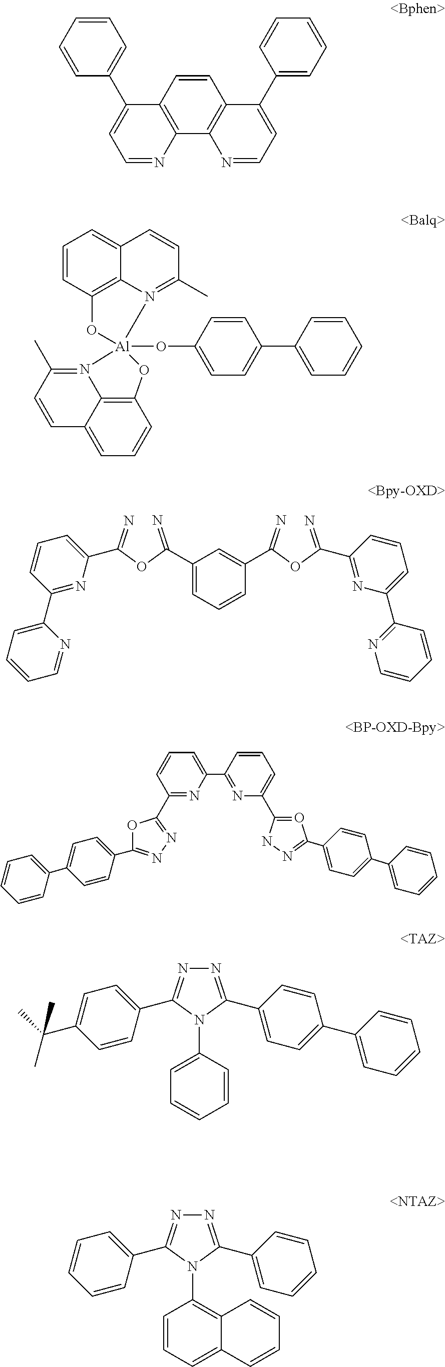

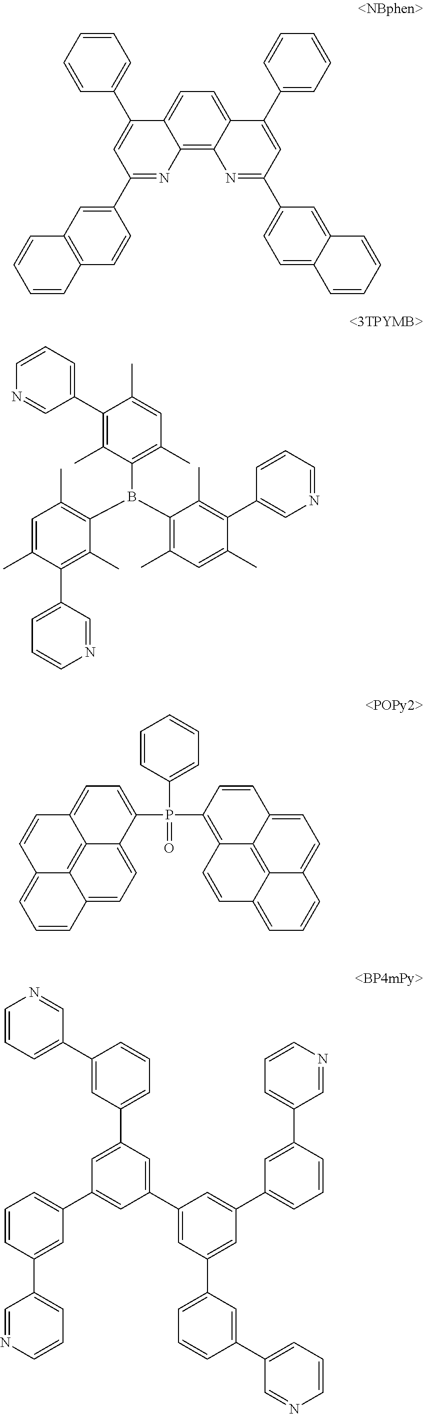 [SMILES: c1ccc(-c2cc(-c3ccc4ccccc4c3)nc3c2ccc2c(-c4ccccc4)cc(-c4ccc5ccccc5c4)nc23)cc1 ; Cc1cc(C)c(-c2cccnc2)c(C)c1B(c1c(C)cc(C)c(-c2cccnc2)c1C)c1c(C)cc(C)c(-c2cccnc2)c1C ; O=P(c1ccccc1)(c1ccc2ccc3cccc4ccc1c2c34)c1ccc2ccc3cccc4ccc1c2c34 ; c1cncc(-c2cccc(-c3cc(-c4cccc(-c5cccnc5)c4)cc(-c4cc(-c5cccc(-c6cccnc6)c5)cc(-c5cccc(-c6cccnc6)c5)c4)c3)c2)c1]

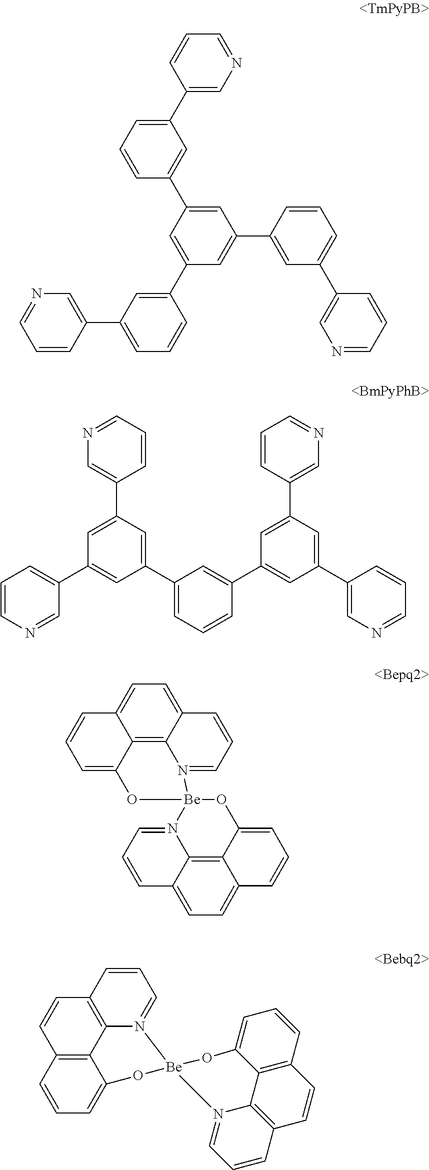

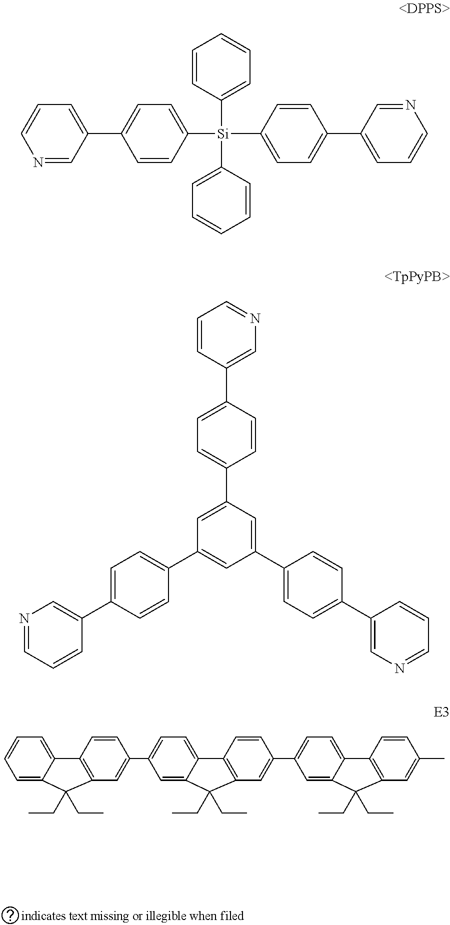

The host of the light emitting layer may further include a hole transport material in addition to one or more of the above described ambipolar transport material and electron transport material.

The hole transport material may be a material having greater hole mobility than electron mobility under the same electric field. For example, the hole transport material may be a material for a hole injection layer or a hole transport layer of an organic light emitting device. For example, the hole transport material may be 1,3-bis(carbazol-9-yl)benzene (MCP), 1,3,5-tris(carbazol-9-yl)benzene (TCP), 4,4′,4″-tris(carbazol-9-yl)triphenylamine (TcTa), 4,4′-bis(carbazol-9-yl)biphenyl (CBP), N,N′-bis(naphthalen-1-yl)-N,N′-bis(phenyl)-benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), di-[4-(N,N-ditolyl-amino)-phenyl]cyclohexane (TAPC), N,N,N′,N′-tetra-naphthalen-2-yl-benzidine (β-TNB), N4,N4,N4′,N4′-tetra(biphenyl-4-yl)biphenyl-4,4′-diamine (TPD15), etc., but is not limited thereto.

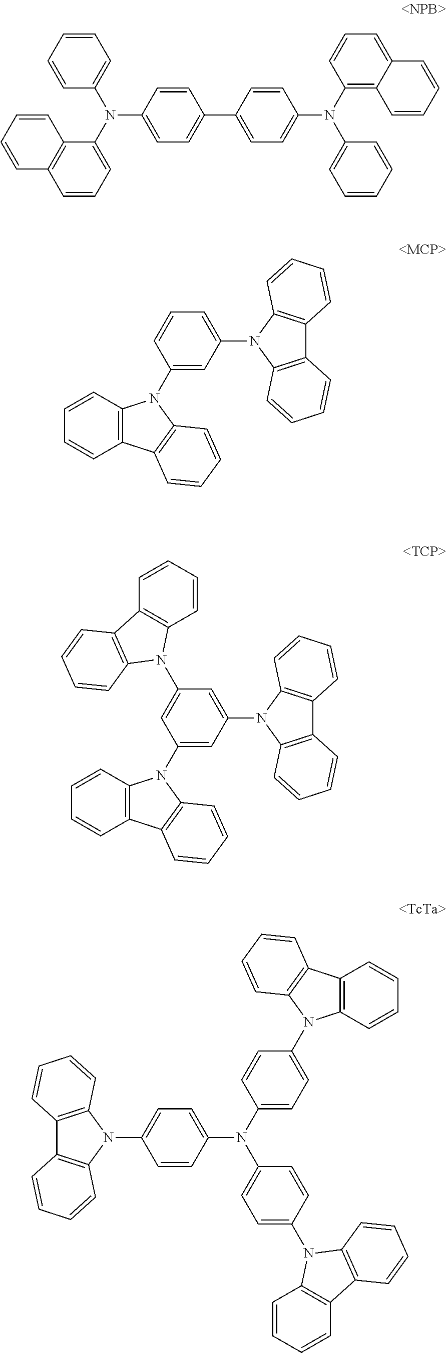 [SMILES: c1ccc(N(c2ccc(-c3ccc(N(c4ccccc4)c4cccc5ccccc45)cc3)cc2)c2cccc3ccccc23)cc1 ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

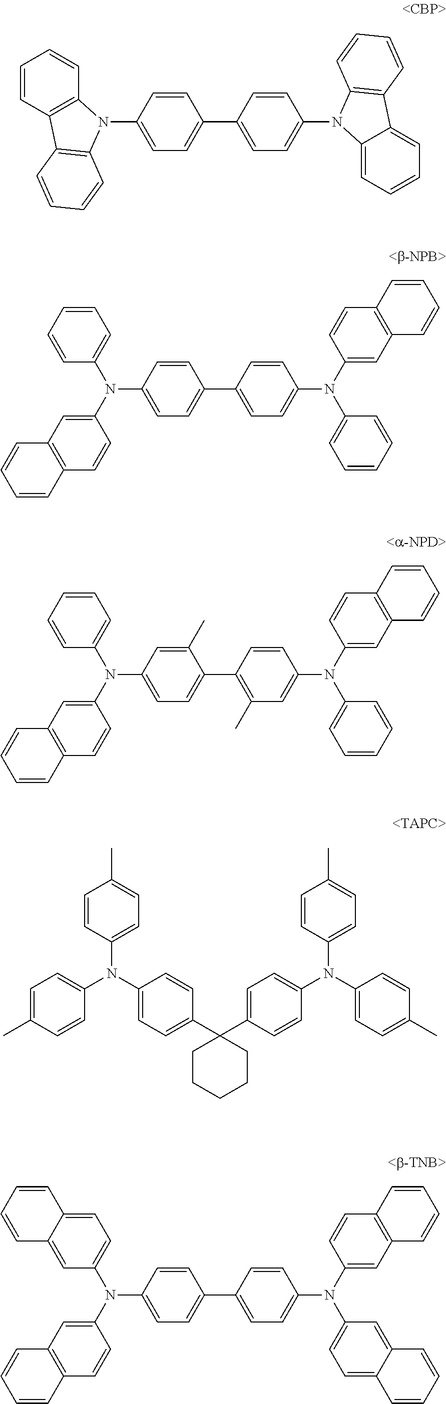

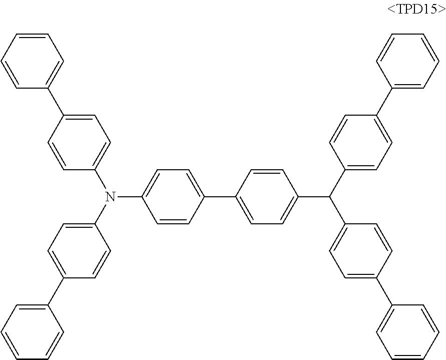 [SMILES: c1ccc(-c2ccc(C(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

As the dopant of the light emitting layer, at least one of red, green, and blue dopants may be used.

As the red dopant of the light emitting layer, rubrene(5,6,11,12-tetraphenylnaphthacene), Pt(II) octaethylporphine (PtOEP), tris(1-phenylisoquinoline)iridium(III) (Ir(piq)₃), bis(1-phenylisoquinoline)(acetylacetonate)iridium(III) (Ir(piq)₂(acac)), Btp₂Ir(acac), 5,6,11,12-tetraphenylnaphthacene (Rubrene), etc. may be used, but is not limited thereto.

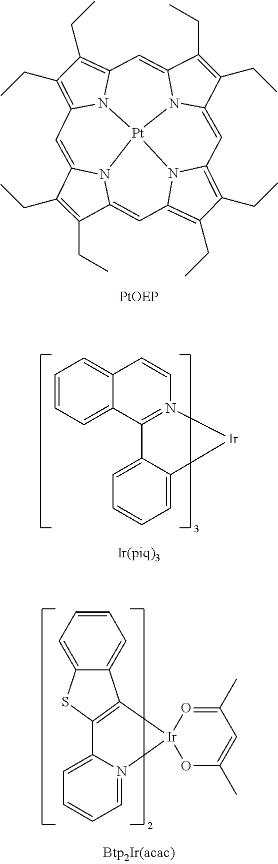

As the green dopant of the low molecular light emitting layer 150, tris(2-phenylpyridine)iridium(III) (Ir(ppy)₃), bis(2-phenylpyridine)(acetylacetonate)iridium(III) (Ir(ppy)₂(acac)), Ir(mpyp)₃, C545T(10-(2-benzothiazolyl)-1,1,7,7-tetramethyl-2,3,6,7-tetrahydro-1H,5H,11H-[1]benzopyrano[6,7,8-ij]quinolizine-11-on, see the following Chemical Formula), etc. may be used, but is not limited thereto.

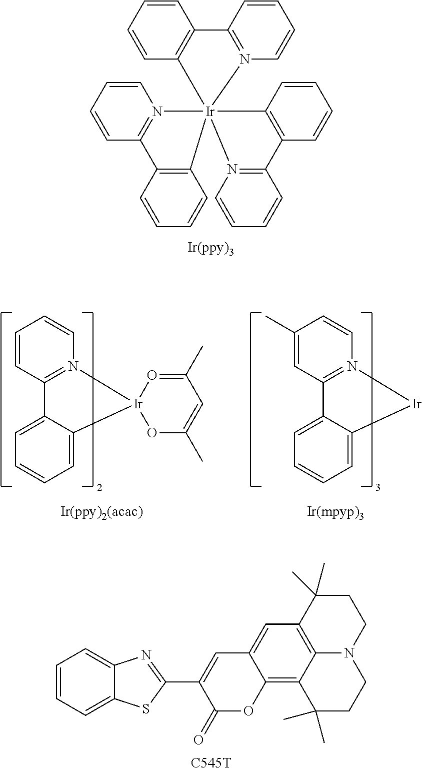

Meanwhile, as the blue dopant of the low molecular light emitting layer 150, bis(3,5-difluoro-2-(2-pyridyl)phenyl-(2-earboxypyridyl)iridium(III) (FIrPic), F₂lrpic, (F₂ppy)₂Ir(tmd), Ir(dfppz)₃, terfluorene, 4,4′-bis[4-(di-p-tolylamino)styryl]biphenyl (DPAVBi), 2,5,8,11-tetra-tert-butyl perylene (TBP), etc. may be used, but is not limited thereto.

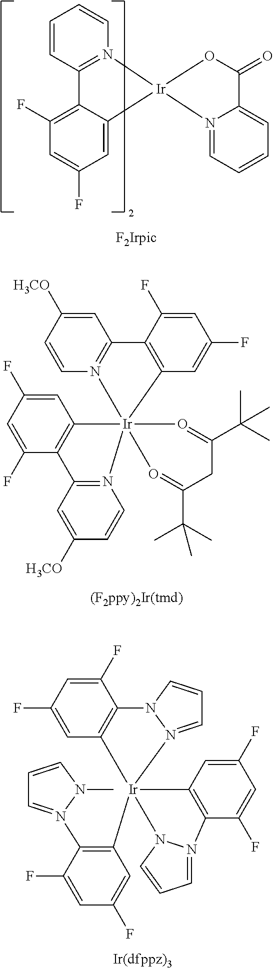

The light emitting layer may implement a red light, a green light, and a blue light by containing respective one of the red, green, and blue dopants, or a white light by containing two or more of the red, green, and blue dopants, and various modifications are possible.

The thickness of light emitting layer may be 2 to 100 nm, for example, 10 to 60 nm. When the thickness of the light emitting layer satisfies the range, excellent light emitting characteristics can be obtained with no increase in driving voltage.

When the organic electronic device is an organic photoelectric device such as organic solar cell or an organic photodetector, the organic active layer 15-3 may be an organic photoelectric conversion layer. The organic photoelectric conversion layer generates excitons through absorption of light, and may be bulk heterojunction (BHJ) layers in which the electron donor material and the electron acceptor material are blended with each other. Alternatively, in the organic photoelectric conversion layer, the electron donor material and the electron acceptor material may be sequentially stacked.

The electron donor material excites electrons from an energy level of the HOMO (Highest Occupied Molecular Orbital) to an energy level of the LUMO (Lowest Unoccupied Molecular Orbital) through absorption of light. Examples of electron donor materials may include polythiophenes, polyfluorene, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, or copolymers thereof.

In one exemplary embodiment, the electron donor material may be poly(3-hexylthiophene; P3HT) which is one form of polythiophene, or poly(cyclopentadithiophene-co-benzothiadiazole) which is one kind of polycyclopentadithiophenes. Poly(cyclopentadithiophene-co-benzothiadiazole) may be PCPDTBT (poly[2,6-(4,4-bis-(2-ethylhexyl)-4H-cyclopenta[2,1-b;3,4-b]dithiophene)-alt-4,7-(2,1,3-benzothiadiazole)]).

The electron acceptor material accepts electrons excited from the electron donor material, and may be C60 to C84 fullerenes or derivatives thereof, such as C60, C70, C76 and C84 fullerenes and derivatives thereof; perylene; polymers; or quantum dots. One example of the fullerene derivatives includes PCBM(C60)([6,6]-phenyl-C61-butyric acid methyl ester) or PCBM(C70)([6,6]-phenyl-C71-butyric acid methyl ester) as examples of PCBM.

The organic photoelectric conversion layer may be formed by dissolving a selected electron donor material and a selected electron acceptor material in a solvent, followed by a solution process. The solvent may be chlorobenzene or dichlorobenzene. If the organic photoelectric conversion layer is a bulk-hetero-junction layer, the donor material and the acceptor material may be mixed in a ratio of 1:0.5 to 1:5 in terms of weight. The solution process may be spin coating, ink jet printing, doctor blade coating, or screen printing. In case that the organic photoelectric conversion layer is formed using the solution process, process cost can be reduced because there is no need of an expensive vacuum equipment, and the solar cell having large area can be implemented. Moreover, in case that the organic photoelectric conversion layer in the organic photoelectric device having large area is separated using the organic fiber pattern, the efficiency of the organic photoelectric device having large area can be improved because the reduction of fill factor and J_{sc} due to the increased area of the device can be prohibited.

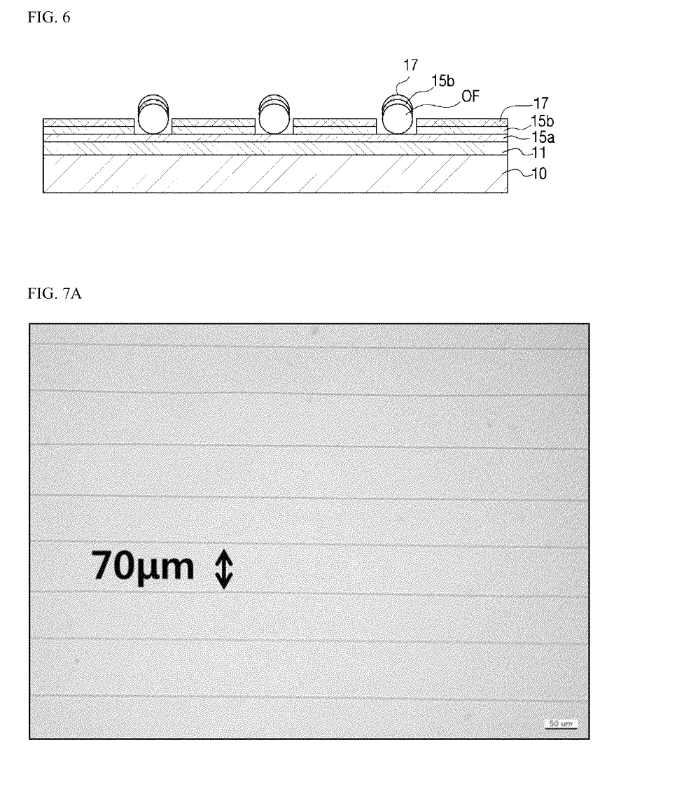

FIG. 6 is a cross-sectional view showing an organic electronic device according to an embodiment of the inventive concept. The organic electronic device according to the embodiment of the inventive concept is similar to the organic electronic device described with reference to FIGS. 3A, 3B, 4A, 4B, and 5A except the following descriptions.

Referring to FIG. 6, a first electrode 11 is formed on a substrate 10. The first electrode 11 may be a plurality of patterns arranged in parallel in one direction. A first organic layer 15a may be formed on the first electrode 11. The first organic layer 15a may be formed on the entire surface of the substrate 10.

Organic fibers OF may be formed on the first organic layer 15a. The organic fibers OF may be arranged to cross the first electrode 11 and have a plurality of patterns in parallel.

A second organic layer 15b and a second electrode 17 may be deposited on the substrate 10 on which the organic fibers OF are arranged. The second organic layer 15b and the second electrode 17 may be formed on an overall portion which is not covered by the organic fibers OF, in particular, a surface of the first organic layer 15a, and on the organic fibers OF. Here, the organic fibers OF may function to prevent the second organic layer 15b and the second electrode 17 formed on the first organic layer 15a from being connected to the second organic layer 15b and the second electrode 17 formed on the organic fibers OF. In this way, when using the organic fibers OF, very simple, fast, and sufficient separation of patterns may be implemented with no complicated process such as a lithography process, used in the art.

The first organic layer 15a may be one or more layers among sequentially stacked hole injection layer 15-1, hole transport layer 15-2, organic active layer 15-3, electron transport layer 15-4, and electron injection layer 15-5, and the second organic layer 15b may be the remaining one or more layers. For example, the first organic layer 15a may include the sequentially stacked hole injection layer 15-1 and hole transport layer 15-2, and the second organic layer 15b may include the sequentially stacked organic active layer 15-3, electron transport layer 15-4, and electron injection layer 15-5.

As another example, the first organic layer 15a may be formed by a liquid-phase process, for example, spin coating. When a material layer is formed on the organic fibers OF using the liquid-phase process after the organic fibers OF are arranged, separation of the material layer by the organic fibers OF may not be easy due to the flow of a liquid used in the liquid-phase process. Accordingly, the first organic layer 15a may be formed by the liquid-phase process before the organic fibers OF are arranged.

The first organic layer 15a using the liquid-phase process may be a layer using a hole-conducting polymer. For example, the first organic layer 15a may be the hole injection layer 15-1 and/or the hole transport layer 15-2.

For example, the hole-conducting polymer, specifically, the polymer included in the hole injection layer 15-1 may include polythiophene, polyaniline, polypyrrole, polystyrene, sulfonated polystyrene, poly(3,4-ethylenedioxythiophene), a self-doping conductive polymer, a derivative thereof, or a combination of two or more thereof. The derivative may further include various kinds of sulfonic acids.

For example, the polymer may include polyaniline/dodecylbenzene sulfonic acid (Pani:DBSA, see the following Chemical Formula), poly(3,4-ethylenedioxythiophene)/poly(4-styrenesulfonate) (PEDOT:PSS, see the following Chemical Formula), polyaniline/camphor sulfonic acid (Pani:CSA), or polyaniline/poly(4-styrenesulfonate) (PANI:PSS), etc., but is not limited thereto.

Examples of the polymer is following, but is not limited hereto:

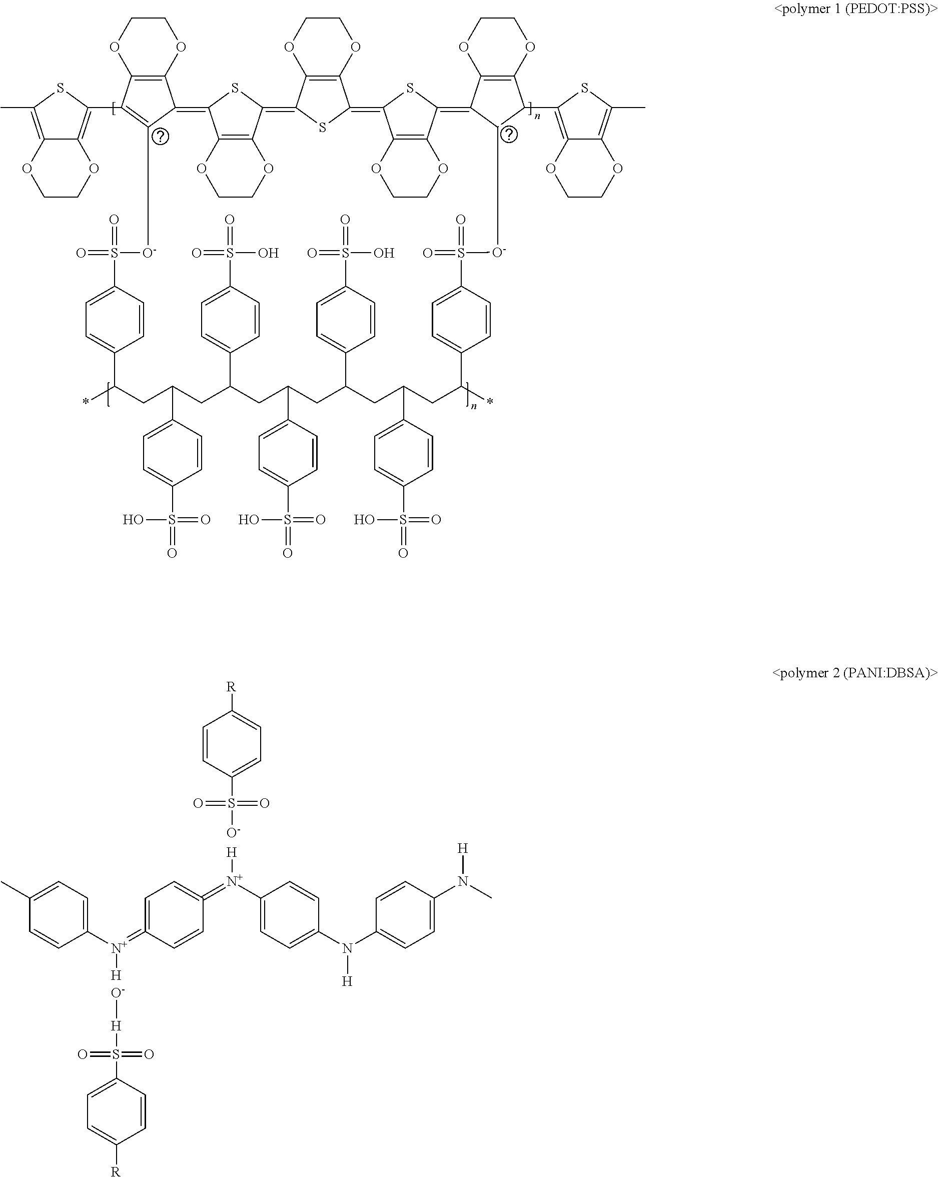

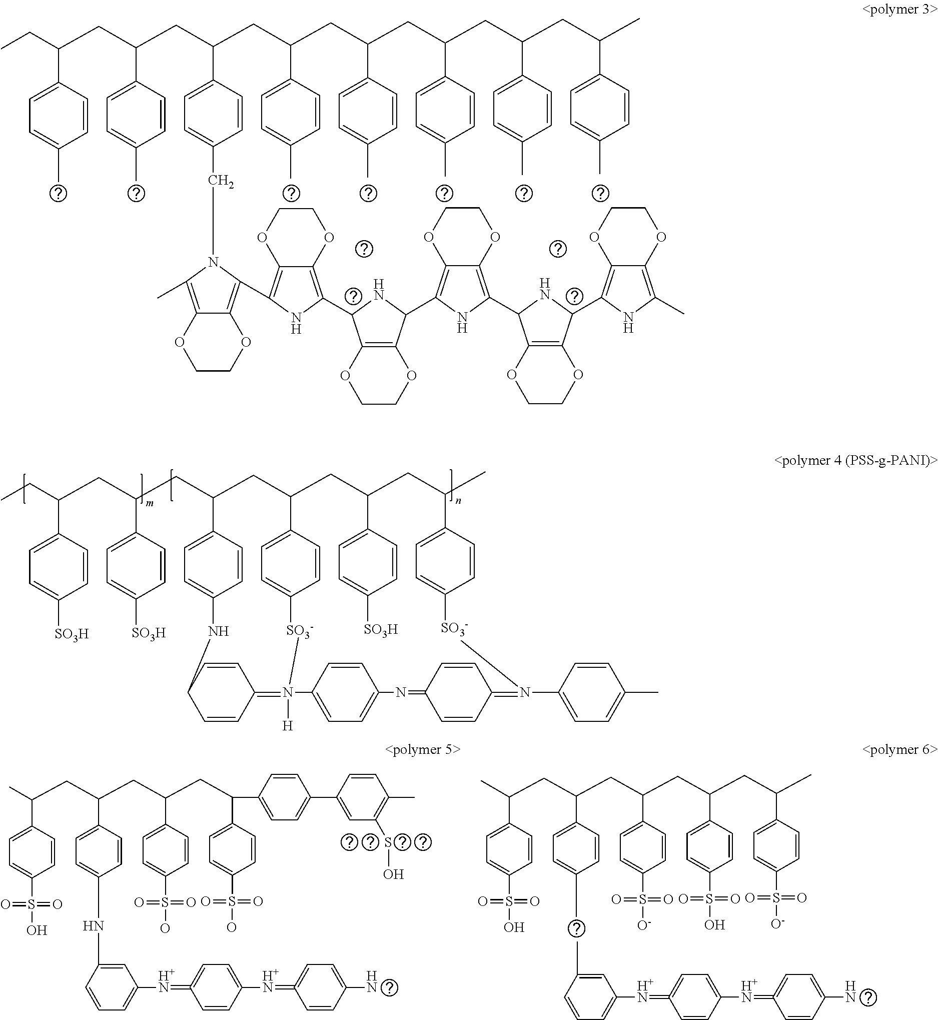

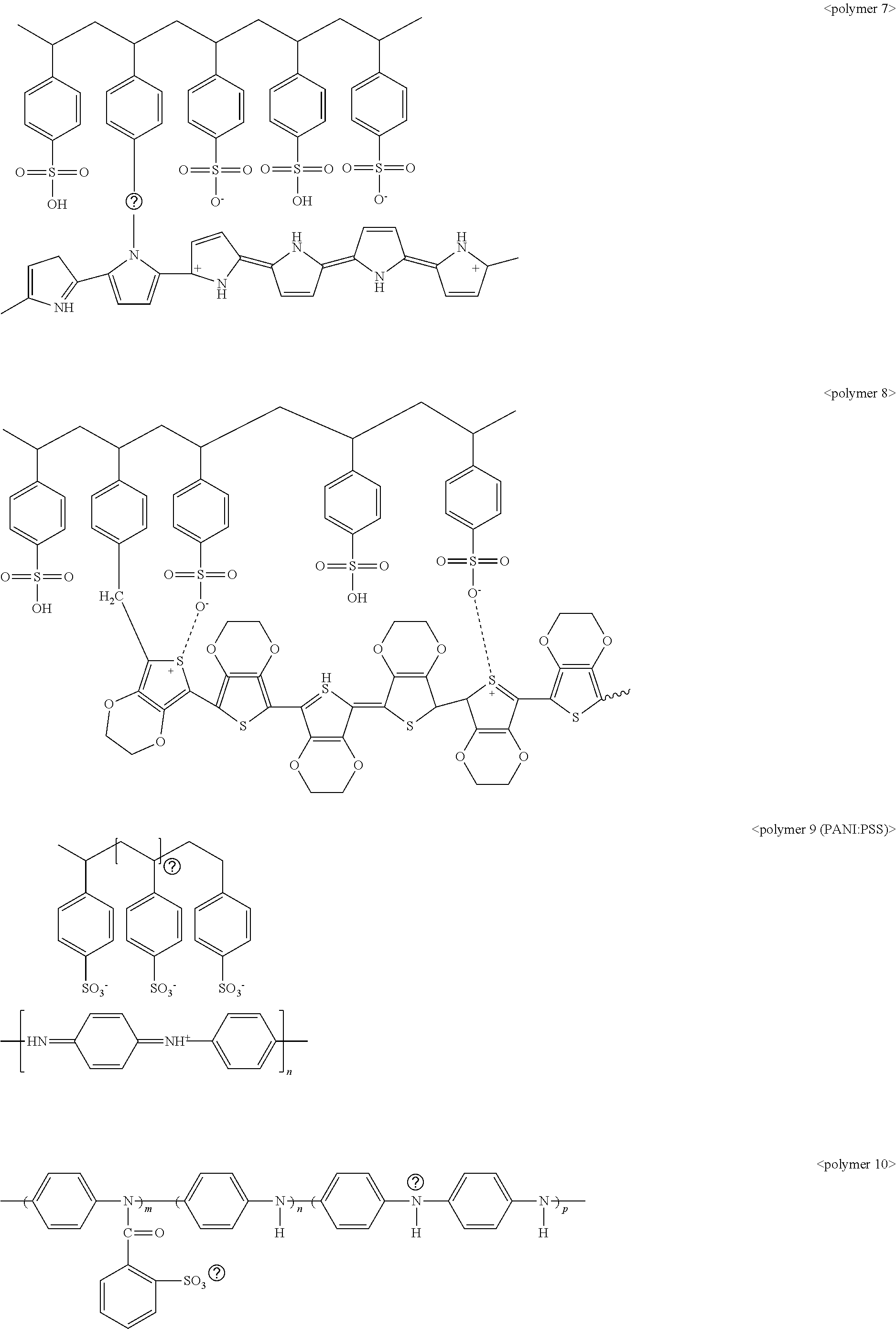

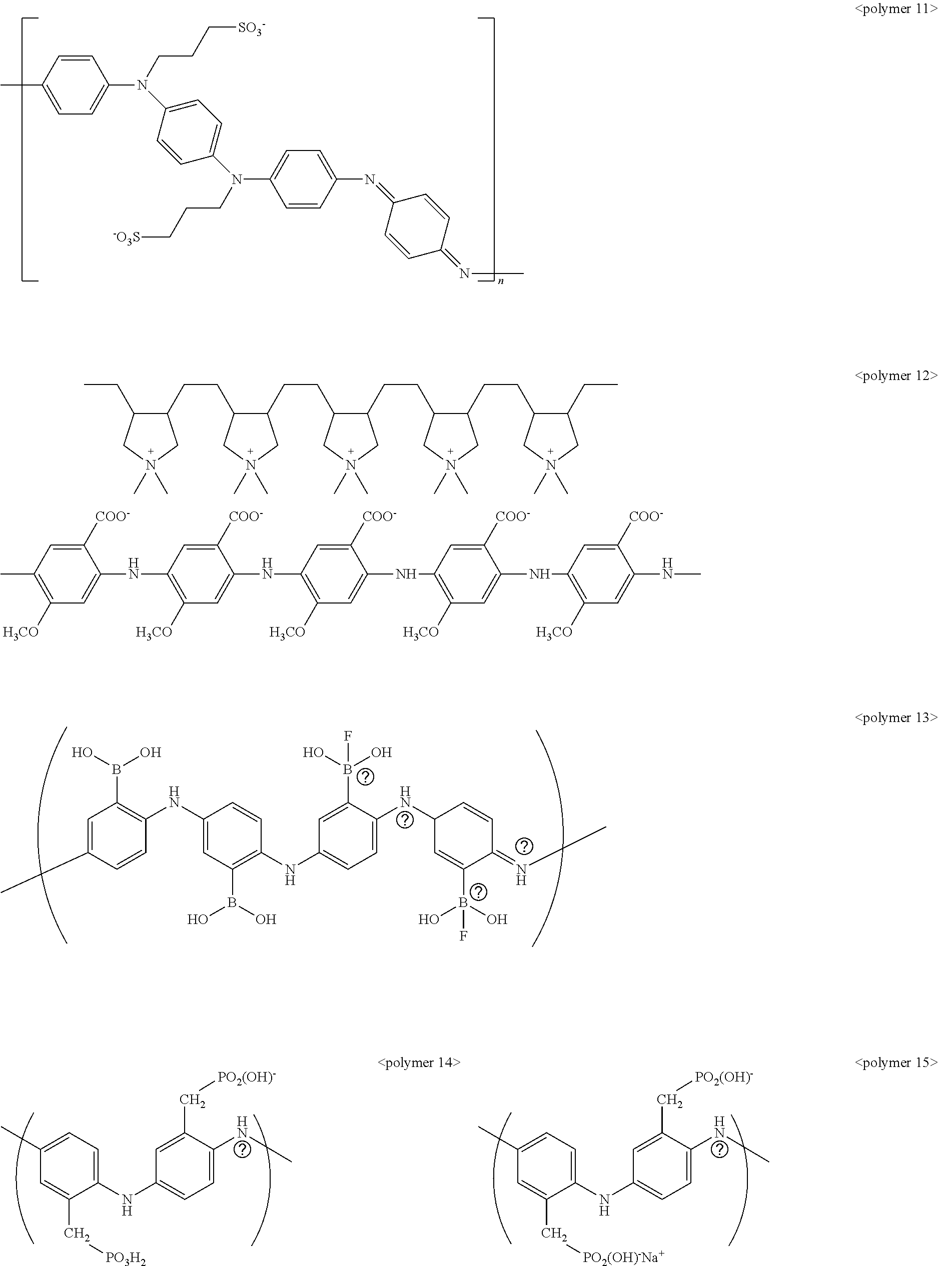

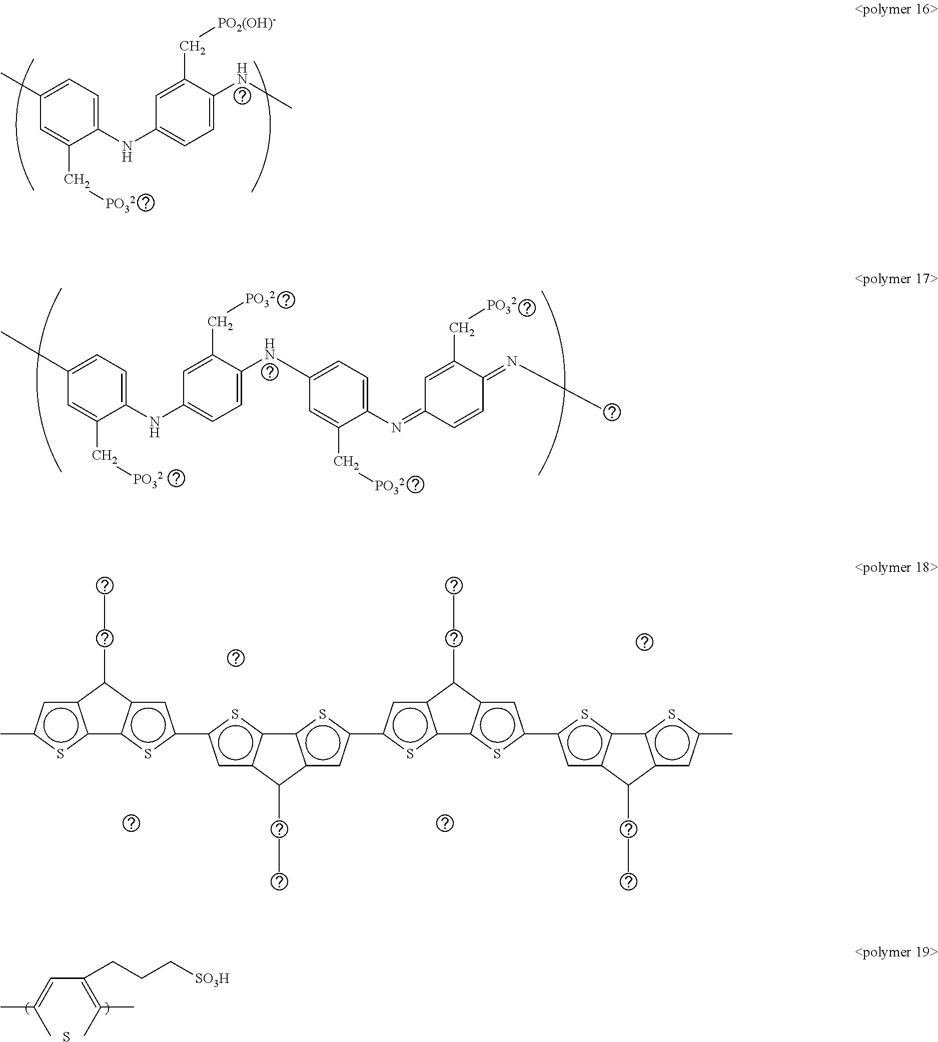

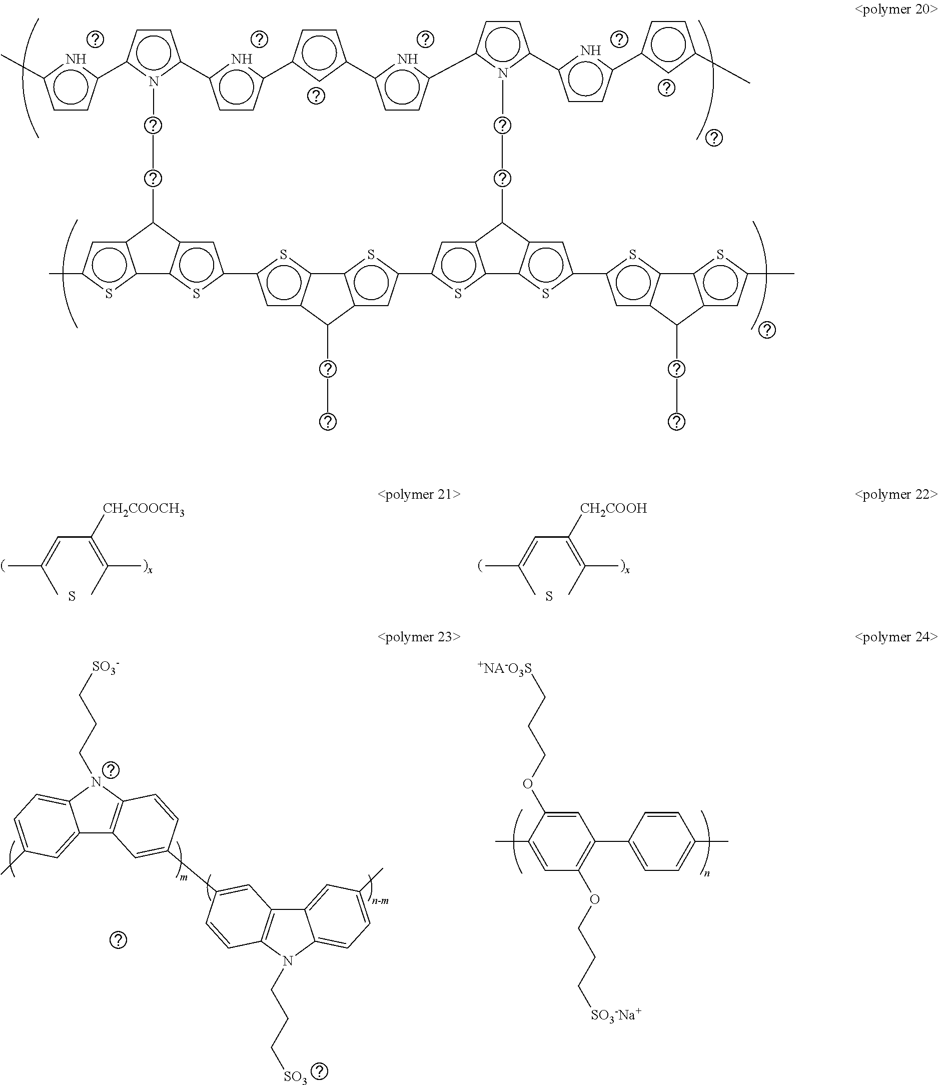

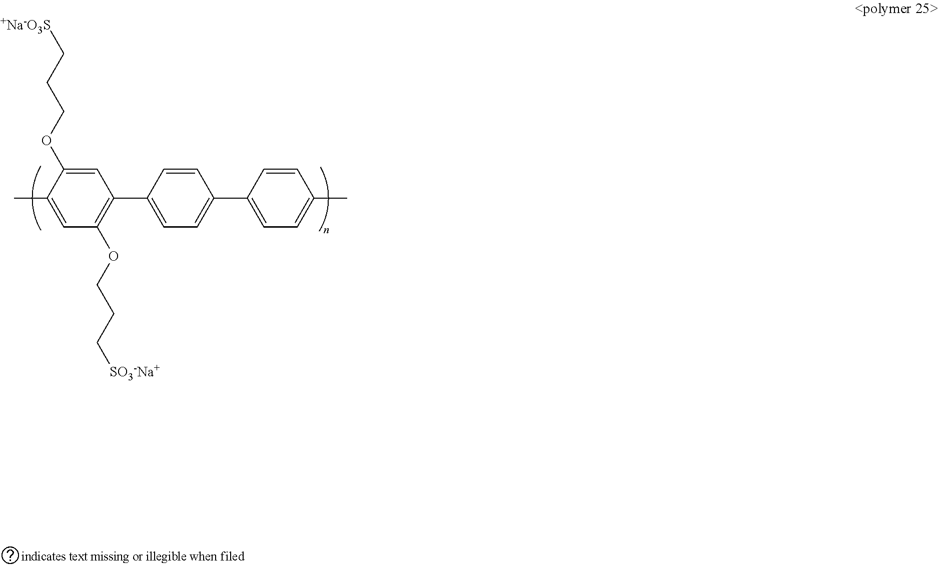

However, at least one of the hole injection layer 15-1, the hole transport layer 15-2, the electron transport layer 15-4, and the electron injection layer 15-5 can be omitted.

Hereinafter, an exemplary example will be provided for easier understanding of the present invention. However, the following experimental examples are only for easier understanding of the present invention, and the inventive concept is not limited by the following experimental examples.

### Preparative Example of Fiber Pattern

A PVK (poly(N-vinylcarbazole)) solution was fabricated by dissolving PVK in styrene. The PVK solution was contained in a syringe of a field-aided robotic nozzle printer, and discharged from a nozzle while applying a voltage to the nozzle. A PVK nanofiber mask pattern was formed on a substrate on a collector moved by a robot stage. Here, a diameter of the nozzle was 100 μm, a distance between the nozzle and the collector was about 4.0 mm, an applied voltage was 2.3 kV, and a discharging rate of the solution was 120 nl/min. A moving pitch of the robot stage in a y-axis direction was 70 μm, and a moving distance of the robot stage in an x-axis direction was 10 cm. A moving speed of the robot stage was 1,000 mm/min in the y-axis direction and 1,000 mm/min in the x-axis direction. Polymer (PVK) nanofiber patterns extending in the x-axis direction, and having a pitch of about 70 μm in the y-axis direction and a diameter of about 1 μm were formed.

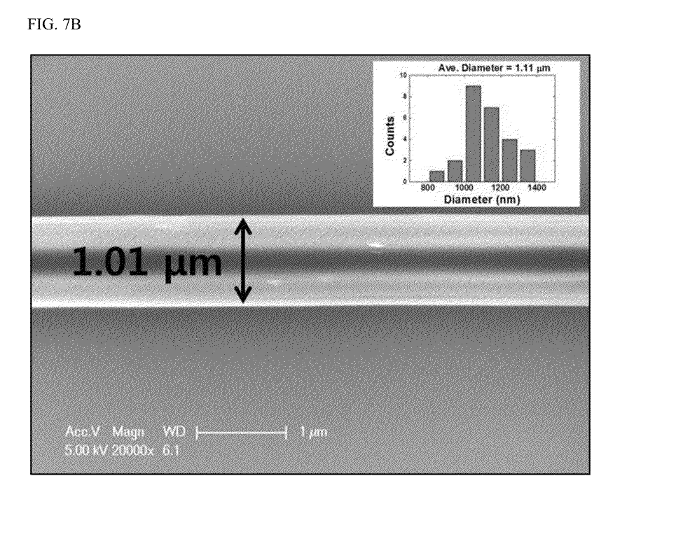

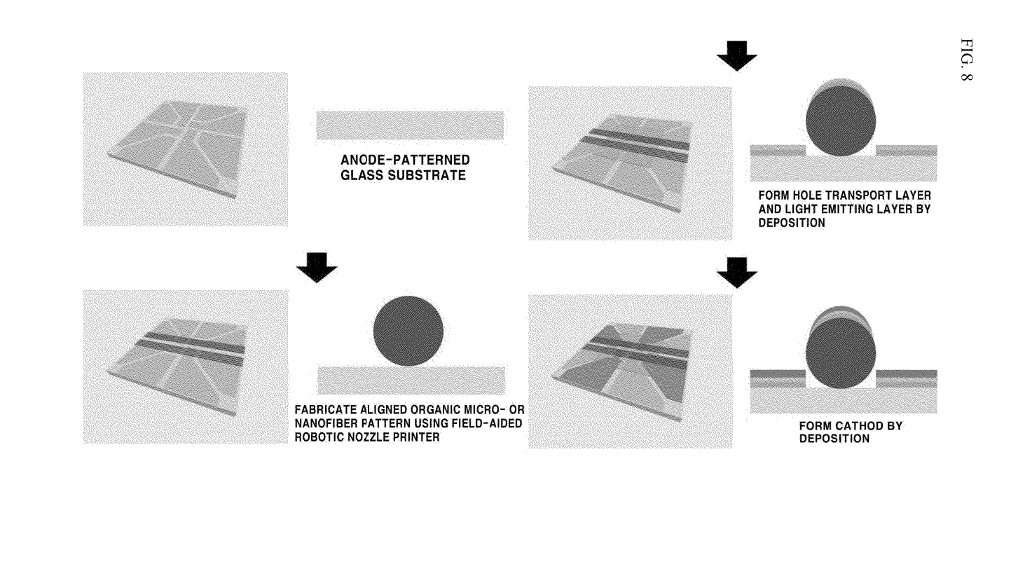

FIG. 7A is an optical microscope (OM) photograph of a PVK fiber pattern formed by Preparative Example of a fiber pattern. Referring to FIG. 7A, a pitch of the aligned PVK fiber patterns may be about 70 μm.

FIG. 7B shows a SEM photograph and a diameter distribution chart of a PVK fiber pattern formed by Preparative Example of a fiber pattern. Referring to FIG. 7B, a diameter of the PVK fiber pattern was 1.01 μm, and an average diameter of the PVK fiber pattern was 1.11 μm.

### Preparative Example 1 of Organic Light Emitting Diode

FIG. 8 is a schematic diagram showing a process of forming the organic light emitting diode according to Preparative Example 1. Referring to FIG. 8, a glass substrate on which an ITO anode is formed was provided. A PEDOT:PSS hole injection layer having a thickness of 50 nm was formed on the anode, and then PVK fiber patterns aligned at 400 μm pitch according to the method described in Preparative Example of a fiber pattern. Next, a TAPC hole transport layer having a thickness of 15 nm, an organic light emitting layer including TCTA:Ir(ppy)₃ (Ir(ppy)₂(acac) 3 wt %) having a thickness of 5 nm and CBP:Ir(ppy)₃ (Ir(ppy)₃ 4 wt %) having a thickness of 5 nm, a TPBI electron transport layer having a thickness of 55 nm, an LiF electron injection layer having a thickness of 1 nm, and an Al cathode having a thickness of 40 nm were sequentially formed on the PVK fiber pattern and the hole injection layer (using a vacuum deposition method). Thus, an organic light emitting diode was fabricated.

### Preparative Example 2 of Organic Light Emitting Diode

An organic light emitting diode was fabricated using the same method as Preparative Example 1 of an organic light emitting diode, except that a pitch between the aligned PVK fiber patterns is 200 μm.

### Preparative Example 3 of Organic Light Emitting Diode

An organic light emitting diode was fabricated using the same method as Preparative Example 1 of an organic light emitting diode, except that a pitch between the aligned PVK fiber patterns is 100 μm.

### Preparative Example 4 of Organic Light Emitting Diode

An organic light emitting diode was fabricated using the same method as Preparative Example 1 of an organic light emitting diode, except that a pitch between the aligned PVK fiber patterns is 50 μm.

### Comparative Example

An organic light emitting diode was fabricated using the same method as Preparative Example 1 of an organic light emitting diode, except that the aligned PVK nanofiber patterns were not formed.

### Cathode Separation Example

Aligned PVK fiber patterns were formed on a silicon substrate, and only an aluminum layer was formed on the PVK fiber pattern.

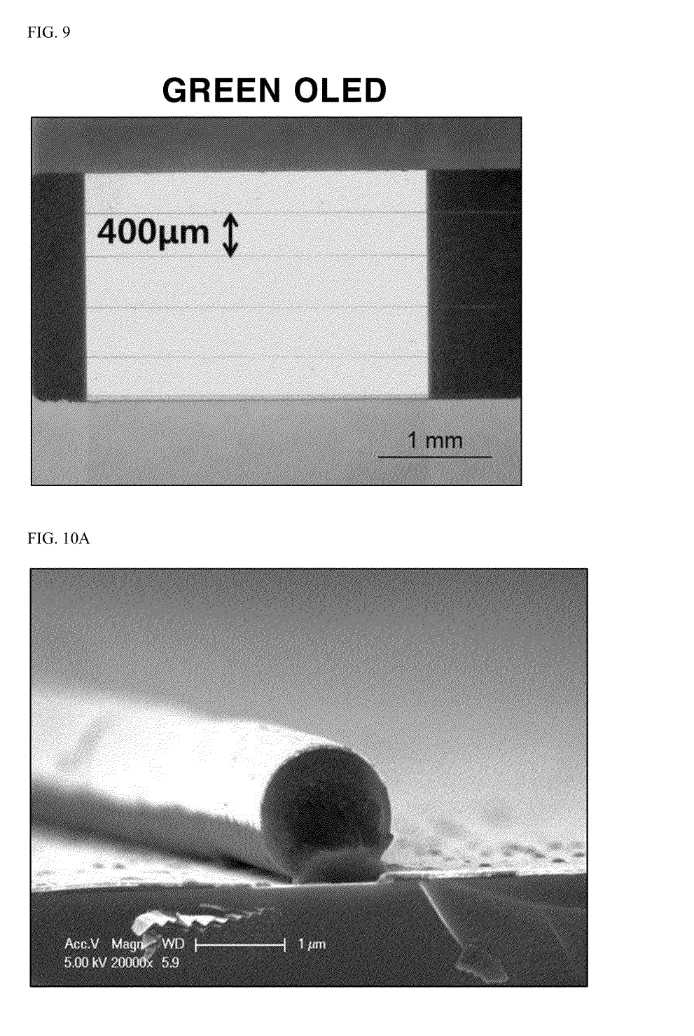

FIG. 9 is a stereoscopic micrograph taken while driving an organic light emitting diode according to Preparative Example 1 of an organic light emitting diode.

Referring to FIG. 9, the organic light emitting diode including the PVK nanofiber pattern formed to have a uniform pitch of 400 μm emits green light at 3.5 V. In addition, it was found that six unit pixels were formed by the aligned PVK nanofibers.

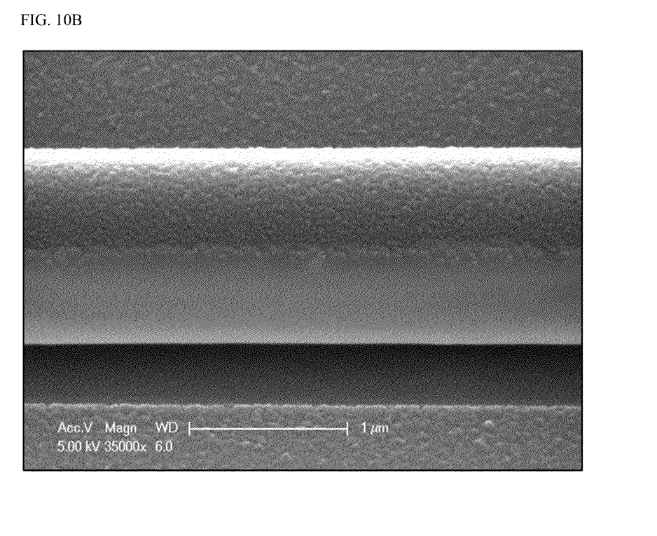

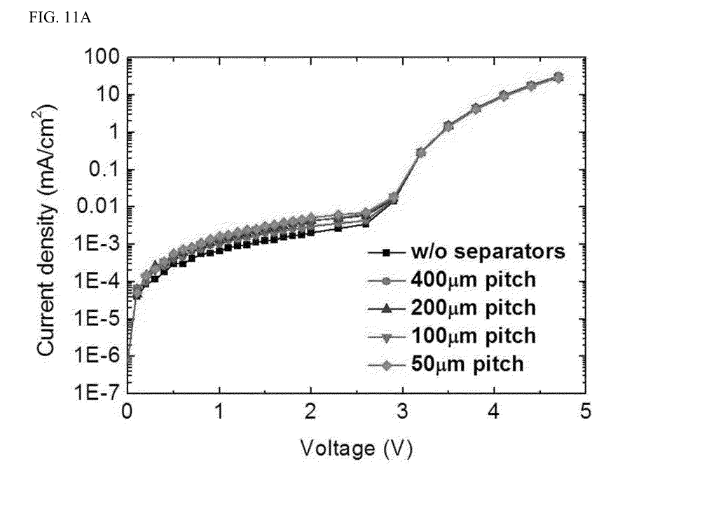

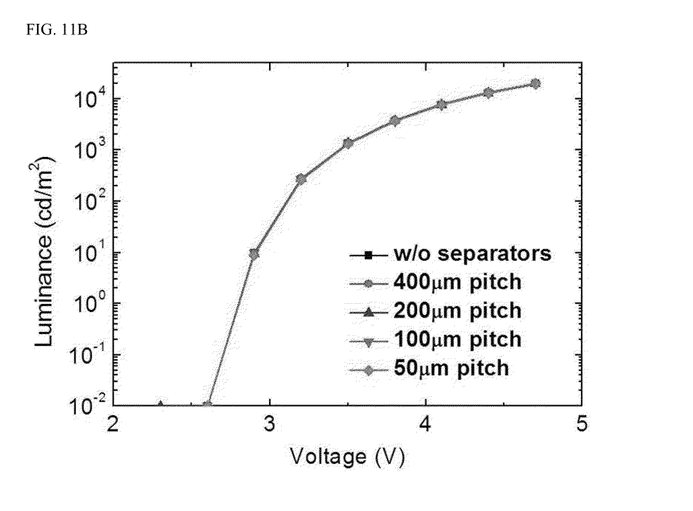

FIGS. 10A and 10B are SEM photographs respectively showing a cross-section and a side surface of a result according to the Cathode Separation Example.

Referring to FIGS. 10A and 10B, aluminum deposited on the aligned PVK nanofiber pattern and the silicon substrate was separated into an aluminum pattern deposited on the silicon substrate and an aluminum pattern deposited on the PVK nanofiber pattern.

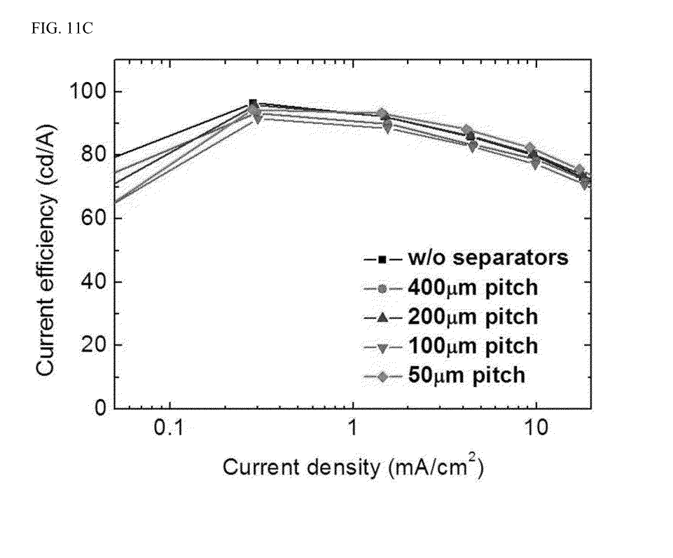

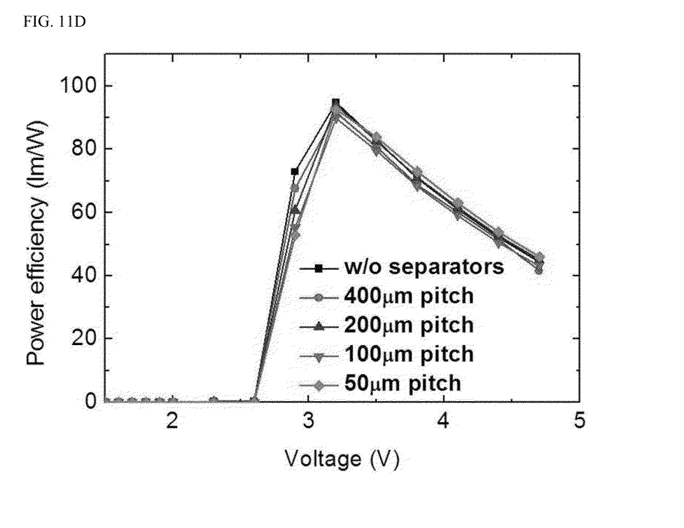

FIGS. 11A, 11B, 11C, and 11D are a graph showing current density vs. voltage characteristics (11A), a graph showing brightness vs. voltage characteristics (11B), a graph showing current efficiency vs. current density characteristics (11C), and a graph showing power efficiency vs. voltage characteristics (11D), of organic light emitting diodes according to Preparative Examples 1 to 4, and Comparative Example.

Referring to FIGS. 11A, 11B, 11C, and 11D, performances of the organic light emitting diodes including the aligned PVK fiber pattern are similar to a performance of the organic light emitting diode which does not include the PVK fiber pattern.

### Preparative Example 5 of Organic Light Emitting Diode

A glass substrate on which five lines of ITO anodes are formed in parallel was provided. A PEDOT:PSS hole injection layer having a thickness of 50 nm was formed on the anode, and four PVK fiber patterns aligned to have a pitch of 400 μm were formed to cross the anodes according to the method described in Preparative Example of a fiber pattern. Next, a TAPC hole transport layer having a thickness of 15 nm, an organic light emitting layer including TCTA:Ir(ppy)₃ (Ir(ppy)₂(acac) 3 wt %) having a thickness of 5 nm and CBP:Ir(ppy)₃ (Ir(ppy)₃ 4 wt %) having a thickness of 5 nm, a TPBI electron transport layer having a thickness of 55 nm, an LiF electron injection layer having a thickness of 1 nm, and an Al cathode having a thickness of 40 nm were sequentially formed on the PVK fiber patterns and the hole injection layer (using a vacuum deposition method). Thus, an organic light emitting diode was fabricated.

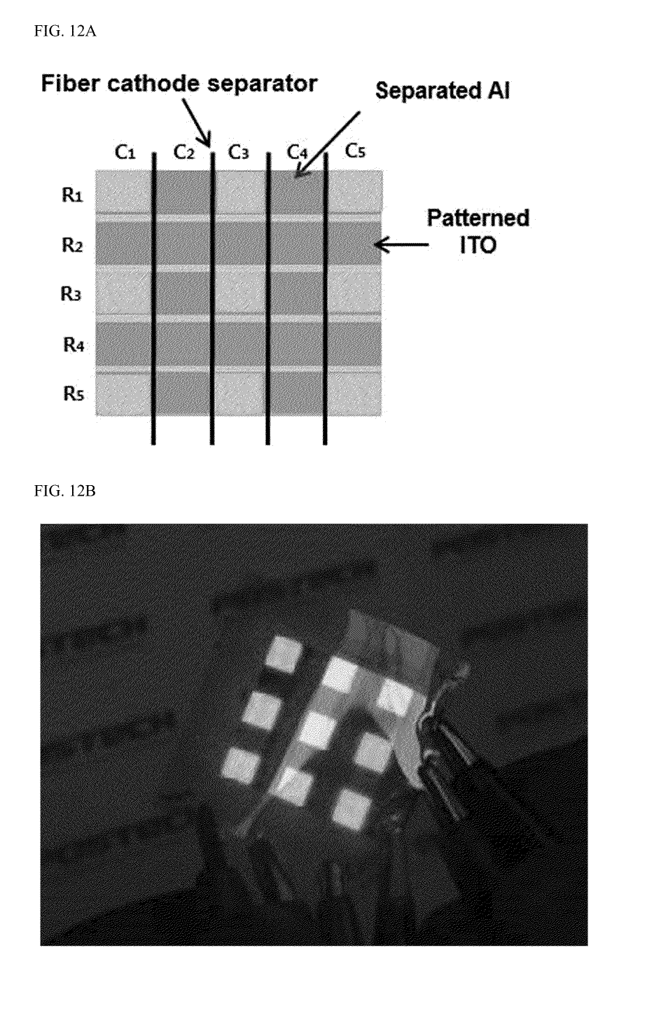

FIG. 12A is a plan view showing an organic light emitting diode according to Preparative Example 5 of an organic light emitting diode, and FIG. 12B is a photograph taken while driving an organic light emitting diode according to Preparative Example 5 of an organic light emitting diode.

Referring to FIG. 12A, the ITO anodes aligned from first row to fifth row (R₁, R₂, R₃, R₄, and R₅) are arranged. Four fiber patterns are arranged on the anodes to cross the anodes. The Al cathode is separated into first column to fifth column (C₁, C₂, C₃, C₄, and C₅) by the fiber patterns. As a result, 5×5 unit pixels are formed.

Referring to FIG. 12B, a voltage was applied to anodes located in the first row (R₁), the third row (R₃), and the fifth row (R₅) and cathodes located in the first column (C₁), the third column (C₃), and the fifth column (C₅) in the 5×5 unit pixels. As a result, green light was emitted only from the unit pixels located in the coordinates of (R₁, C₁), (R₁, C₃), (R₁, C₅), (R₃, C₁), (R₃, C₃), (R₃, C₅), (R₅, C₁), (R₅, C₃), and (R₅, C₅).

### Preparative Example 6 of Organic Light Emitting Diode

A glass substrate on which an ITO anode having a size of 3 cm×3 cm is formed was provided. A PEDOT:PSS hole injection layer having a thickness of 50 nm was formed on the anode, and two aligned PVK fiber patterns were formed to define three unit pixels having a size of 3 cm×1 cm according to the method described in Preparative Example of a fiber pattern. Next, a TAPC hole transport layer having a thickness of 15 nm, an organic light emitting layer including a TCTA:FIrpic (Flrpic 7 wt %) blue light emitting layer having a thickness of 6.7 nm, a DCzPPy:Bt2Ir(acac) (Bt2Ir(acac) 3 wt %) orange light emitting layer having a thickness of 0.6 nm, and a DCzPPy:Flrpic (Flrpic 20 wt %) blue light emitting layer having a thickness of 6.7 nm, a 3TPYMB electron transport layer having a thickness of 40 nm, an LiF electron injection layer having a thickness of 1 nm, and an Al cathode having a thickness of 40 nm were sequentially formed on the PVK fiber patterns and the hole injection layer (using a vacuum deposition method). Thus, an organic light emitting diode was fabricated.

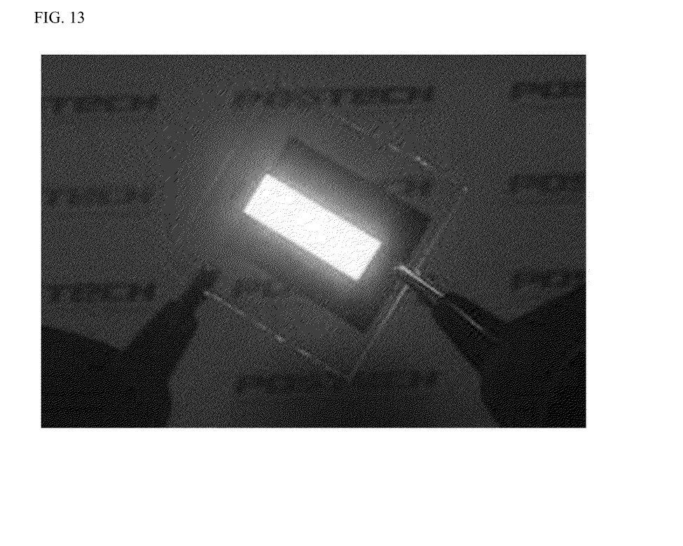

FIG. 13 is a photograph taken while driving an organic light emitting diode according to Preparative Example 6 of an organic light emitting diode.

Referring to FIG. 13, even in a relatively large organic light emitting diode having a size of 3 cm×3 cm, pixels are separated well by the fiber patterns.

According to the embodiments of the present invention, by arranging organic fibers and coating the organic fibers with a material layer, very simple, fast, and sufficient separation of patterns may be implemented with no complicated process such as a lithography process, used in the art.

In addition, when a cross-section of the organic fibers has a circular or oval shape, pattern separation may be easier.

In particular, when using a field-aided robotic nozzle printer by inventors of the embodiments of the present invention, the number and the pitch of the organic fibers may be precisely adjusted and the organic fibers may be precisely formed to have a large area at a preferred position. Accordingly, a preferred number and size of unit pixels may be formed. Further, since a process performed by the field-aided robotic nozzle printer is very simple and fast, the performance of the organic electronic device is hardly affected.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. An organic electronic device, comprising:
a substrate;
an organic fiber disposed on the substrate; and
material patterns disposed on exposed surfaces of the substrate at both sides of the organic fiber and separated by the organic fiber.

2. The organic electronic device of claim 1, wherein the material patterns include at least one of an organic semiconductor layer, an organic conductive layer, an inorganic semiconductor layer, and an inorganic metal electrode.

3. The organic electronic device of claim 1, further comprising a first electrode disposed between the organic fiber and the substrate,
wherein the material patterns include a second electrode.

4. The organic electronic device of claim 3, wherein the material patterns include a sequentially stacked organic active layer and second electrode,
wherein the organic active layer is an organic light emitting layer or an organic photoelectric conversion layer.

5. The organic electronic device of claim 4, further comprising at least one of a hole injection layer and a hole transport layer disposed between the first electrode and a bottom of the organic fiber.

6. The organic electronic device of claim 5, wherein at least one of the hole injection layer and the hole transport layer is a hole-conducting polymer layer.

7. The organic electronic device of claim 6, wherein the hole-conducting polymer layer includes polythiophene, polyaniline, polypyrrole, polystyrene, sulfonated polystyrene, poly (3,4-ethylenedioxythiophene), a self-doped conductive polymer, a derivative thereof, or a blend of two or more thereof.

8. The organic electronic device of claim 4, further comprising at least one of an electron transport layer and an electron injection layer disposed between the organic active layer and the second electrode.

9. The organic electronic device of claim 1, wherein the organic fiber is an insulating polymer fiber.

10. The organic electronic device of claim 1, wherein a cross-section of the organic fiber has a circular or oval shape.

11. The organic electronic device of claim 1, wherein the organic fiber has a diameter of 10 nm to 100 p.m.

12. The organic electronic device of claim 1, wherein the organic fiber is a plurality of organic fibers spaced apart from each other, and
an angle formed by the organic fibers is in the range of 0° to 10°.

13. The organic electronic device of claim 1, wherein the organic fiber is a plurality of organic fibers spaced apart from each other, and
each of the plurality of organic fibers has straightness with respect to a diameter thereof within the range of 0% to 10%.

14. A method of forming an organic electronic device, comprising:
arranging organic fibers on a substrate; and
depositing a material layer on the substrate, on which the organic fibers are formed, to form material patterns separated by the organic fibers on the substrate.

15. The method of claim 14, wherein the organic fibers are formed by printing an organic solution obtained by mixing an organic material in distilled water or an organic solvent on the substrate.

16. The method of claim 15, wherein the organic material is an organic insulating polymer selected from a group consisting of PEO(Polyethylene oxide), PS(Polystyrene), PCL(Polycaprolactone), PAN(Polyacrylonitrile), PMMA(Poly(methyl methacrylate)), Polyimide, PVDF(Poly(vinylidene fluoride)), PVK(Poly(n-vinylcarbazole)), PVC(Polyvinylchloride), and photoresist.

17. The method of claim 15, wherein the organic solvent is a solvent selected from a group consisting of dichloroethylene, trichloroethylene, chloroform, chlorobenzene, dichlorobenzene, styrene, dimethylformamide, dimethylsulfoxide, xylene, toluene, cyclohexene, isopropyl alcohol, ethanol, acetone and mixtures thereof.

18. The method of claim 15, wherein the printing is performed using electric field aided robotic nozzle printing, direct tip drawing, meniscus-guided direct writing, melt spinning, wet spinning, dry spinning, gel spinning, or electrospinning.

19. The method of claim 18, wherein the electric field aided robotic nozzle printing is performed using a printer including a solution storage apparatus supplying the organic solution, a nozzle discharging the organic solution received from the solution storage apparatus, a voltage applying apparatus applying high voltage to the nozzle, a collector having a flat shape and being movable, a robot stage moving the collector along x and/or y directions, a micro distance controller controlling the distance between the nozzle and the collector along z direction, and a base plate maintaining flatness of the collector and preventing vibrations generated by an operation of the robot stage.

20. The method of claim 19, wherein a distance between the nozzle and the collector is in the range of about 10 μm to about 20 mm.

21. The method of claim 19, wherein printing the organic fibers includes:
adding the organic solution into the solution storage apparatus;
discharging the organic solution from the nozzle while applying high voltage on the nozzle by using the voltage applying apparatus; and
aligning, on a substrate placed on the collector while moving the collector, the organic fibers formed from the organic solution being discharged from the nozzle.

22. The method of claim 14, wherein the material layer includes at least one of an organic semiconductor layer, an organic conductive layer, an inorganic semiconductor layer, and an inorganic metal electrode.

23. The method of claim 14, further comprising forming a first electrode on the substrate before the organic fibers are arranged,
wherein the depositing the material layer includes depositing a second electrode.

24. The method of claim 23, wherein the depositing the material layer further comprises depositing an organic active layer before depositing the second electrode,
wherein the organic active layer is an organic light emitting layer or an organic photoelectric conversion layer.

25. The method of claim 24, further comprising forming at least one of a hole injection layer and a hole transport layer on the first electrode before arranging the organic fibers.

26. The method of claim 25, wherein at least one of the hole injection layer and the hole transport layer is a hole conducting polymer layer formed by a liquid-phase process.

27. The method of claim 26, wherein the hole-conducting polymer layer includes polythiophene, polyaniline, polypyrrole, polystyrene, sulfonated polystyrene, poly (3,4-ethylenedioxythiophene), a self-doped conductive polymer, a derivative thereof, or a blend of two or more thereof.

28. The method of claim 23, further comprising forming a first organic layer on the first electrode before arranging the organic fibers,
wherein the depositing the material layer further comprises depositing a second organic layer including an organic active layer before depositing the second electrode, and
the organic active layer is an organic light emitting layer or an organic photoelectric conversion layer.

29. The method of claim 28, wherein the first organic layer is formed by a liquid-phase process.

30. The method of claim 14, wherein a cross-section of the organic fibers has a circular or oval shape.
